(19) United States
(12) Patent Application Publication
(10) Pub. No.: US 2024/0085794 A1
(43) Pub. Date: Mar. 14, 2024

(54) ILLUMINATION OPTICAL SYSTEM, EXPOSURE DEVICE AND METHOD FOR MANUFACTURING FLAT PANEL DISPLAY

(71) Applicant: NIKON CORPORATION, Tokyo (JP)

(72) Inventors: Masaki KATO, Yokohama-shi (JP); Yasushi MIZUNO, Saitama-shi (JP); Satoshi KAWADO, Tokyo (JP)

(73) Assignee: NIKON CORPORATION, Tokyo (JP)

(21) Appl. No.: 18/383,525

(22) Filed: Oct. 25, 2023

Related U.S. Application Data
(63) Continuation of application No. PCT/JP2022/018810, filed on Apr. 26, 2022.

(30) Foreign Application Priority Data
Apr. 27, 2021 (JP) 2021-075408
Apr. 27, 2021 (JP) 2021-075409
Apr. 27, 2021 (JP) 2021-075410

(51) Int. Cl. G03F 7/20; G02B 6/35; G02B 26/10

(52) U.S. Cl. CPC G03F 7/20; G02B 6/3512; G02B 26/10

(57) ABSTRACT

An illumination optical system configured to illuminate a mask on which a predetermined pattern is formed, includes a plurality of light sources configured to emit pulse lights, an optical system including a division part configured to divide the pulse lights emitted from the plurality of light sources into first pulse light and second pulse light, a delay optical system configured to guide the second pulse light to a second optical path longer than a first optical path through which the first pulse light passes, and a synthesis/division part configured to synthesize the first pulse light and the second pulse light passing through the delay optical system and divide and emit the synthesized pulse light, and an illumination system configured to guide the pulse lights emitted from the optical system to the mask and illuminate the mask.

### CROSS-REFERENCE TO RELATED APPLICATION

Priority is claimed on Japanese Patent Application No. 2021-075408, filed Apr. 27, 2021, Japanese Patent Application No. 2021-075409, filed Apr. 27, 2021, and Japanese Patent Application No. 2021-075410, filed Apr. 27, 2021. The present application is a continuation application of International Application PCT/JP2022/018810, filed on Apr. 26, 2022. The contents of the above applications are incorporated herein.

### BACKGROUND

### Technical Field

The present invention relates to an illumination optical system, an exposure device and a method for manufacturing a flat panel display.

In the related art, in a lithography process for manufacturing an electronic device (a micro device) such as a liquid crystal display device, a semiconductor device (integrated circuit or the like), or the like, a step and repeat type projection exposure device (a so-called stepper), a step and scan type projection exposure device (a so-called scanning stepper (also referred to as a scanner)), or the like is mainly used.

In this type of exposure device, a substrate such as a glass plate or a wafer coated with a photosensitizer (hereinafter, generally referred to as a substrate) is placed on a substrate stage device as an exposure object. Then, a circuit pattern is transferred onto a substrate by irradiating a spatial light modulation element, on which a circuit pattern is formed, with pulse light and irradiating a substrate with the pulse light via the spatial light modulation element via an optical system such as a projection lens or the like (for example, see Japanese Unexamined Patent Application, First Publication No. 2006-171426).

### SUMMARY

According to a first aspect of the present invention, there is provided an illumination optical system including: a plurality of light sources each configured to emit pulse light; an optical system including (i) a division part configured to divide the pulse light emitted from each of the plurality of light sources into first pulse light and second pulse light, (ii) a delay optical system configured to guide the second pulse light to a second optical path longer than a first optical path through which the first pulse light passes, and (iii) a synthesis/division part configured to synthesize the second pulse light that has passed through the delay optical system and the first pulse light and to divide and emit the synthesized pulse light; and an illumination system configured to guide the pulse lights emitted from the optical system so as to illuminate a mask on which a predetermined pattern is formed.

According to a second aspect of the present invention, there is provided an illumination optical system including: a plurality of light sources each configured to emit pulse light; an optical system including a synthesis/division part configured to synthesize the pulse light emitted from each of the plurality of light sources, and to divide and emit the synthesized pulse light; and an illumination system configured to guide each of the pulse lights emitted from the optical system so as to illuminate a mask on which a predetermined pattern is formed.

According to a third aspect of the present invention, there is provided an exposure device including: the illumination optical system described above; a projection optical system configured to divisionally expose an exposure target by irradiating an exposure target with light emitted from the mask illuminated by the pulse light; and a stage on which the exposure target is placeable.

According to a fourth aspect of the present invention, there is provided a method for manufacturing a flat panel display including: exposing an exposure target using the exposure device described above; and developing the exposed exposure target.

According to a fifth aspect of the present invention, there is provided an illumination optical system including: a first light source configured to emit first pulse light at a first time point; a second light source configured to emit second pulse light at a second time point different from the first time point; and an illumination system configured to guide each of the first pulse light and the second pulse light to a spatial light modulator in which a plurality of elements are individually controlled at a predetermined time interval, wherein the second light source emits the second pulse light at the second time point in which a time interval from the first time point is shorter than the predetermined time interval.

According to a sixth aspect of the present invention, there is provided an exposure device including: the illumination optical system described above; and a projection optical system configured to divisionally expose a substrate by irradiating the substrate with light emitted from each of the plurality of spatial light modulators illuminated by the first and second pulse lights.

According to a seventh aspect of the present invention, there is provided an exposure device including: the illumination optical system described above; a projection optical system configured to project an image of the spatial light modulator illuminated by the illumination optical system on a substrate; and a substrate stage configured to support the substrate and relatively move with respect to the projection optical system at a predetermined speed when the image of the spatial light modulator is exposed to the substrate, wherein, provided that a time difference between the first time point and the second time point is δ, the predetermined speed is V, and resolution of the image is R, R/3<V·δ is satisfied.

According to an eighth aspect of the present invention, there is provided an exposure device including: the illumination optical system described above; and a projection optical system configured to project an image of the spatial light modulator illuminated by the illumination optical system on a substrate, wherein the first and second light sources emit the first pulse light and the second pulse light that satisfy λ<Δ×(NA\hat{ }2) provided that a wavelength difference between the first pulse light and the second pulse light is λ, chromatic aberration of the projection optical system occurring due to the wavelength difference between the first pulse light and the second pulse light is Δ, and a numerical aperture of the projection optical system is NA.

According to a ninth aspect of the present invention, there is provided a method for manufacturing a flat panel display, including: exposing a substrate for a flat panel display using the exposure device described above; and developing the exposed substrate.

According to a tenth aspect of the present invention, there is provided an illumination method performed in an illumination optical system configured to illuminate a spatial light modulator in which a plurality of elements are individually controlled at a predetermined time interval, the method including: emitting first pulse light from a first light source at a first time point; emitting second pulse light from a second light source at a second time point which is different from the first time point and in which a time interval from the first time point is shorter than the predetermined time interval; and guiding each of the first and second pulse lights to the spatial light modulator and illuminating the spatial light modulator using the illumination optical system.

According to an eleventh aspect of the present invention, there is provided a device manufacturing method including: exposing an image of the spatial light modulator illuminated by the illumination method described above; exposing the illuminated image on a substrate; and developing the exposed substrate.

According to a twelfth aspect of the present invention, there is provided a method for manufacturing a flat panel display, including: exposing an image of the spatial light modulator illuminated by the illumination method described above on a substrate; and developing the exposed substrate.

According to a thirteenth aspect of the present invention, there is provided an illumination optical system including: a light source configured to emit pulse light; an optical system including (i) a division part configured to divide the pulse light into first pulse light and second pulse light, (ii) a delay optical system configured to guide the second pulse light to a second optical path longer than a first optical path through which the first pulse light passes, and (iii) a synthesis part configured to synthesize the second pulse light which has passed through the delay optical system and the first pulse light; and an illumination system configured to guide the first and second pulse lights synthesized by the synthesis part to a mask on which a predetermined pattern is formed, wherein the delay optical system includes a reflection part configured to reflect the second pulse light, and an optical member configured to cause the reflected second pulse light to enter the reflection part again.

According to a fourteenth aspect of the present invention, there is provided an illumination optical system including: a light source configured to emit pulse light; an optical system including (i) a division part configured to divide the pulse light into first pulse light and second pulse light, (ii) a delay optical system configured to guide the second pulse light to a second optical path longer than a first optical path through which the first pulse light passes, and (iii) a synthesis part configured to synthesize the second pulse light which has passed through the delay optical system and the first pulse light; and an illumination system configured to guide the first and second pulse lights synthesized by the synthesis part to a mask on which a predetermined pattern is formed, wherein the delay optical system includes a reflection part configured to reflect the second pulse light and to guide the reflected second pulse light to the synthesis part, and an optical member that is disposed between the division part and the reflection part and between the reflection part and the synthesis part, that is configured to cause the second pulse light to enter the reflection part, and that is configured to cause the second pulse light reflected by the reflection part to enter the synthesis part, and the delay optical system includes the division part and the synthesis part that are provided at positions where a division surface of the division part configured to divide the pulse light into the first pulse light and the second pulse light and a synthesis surface of the synthesis part configured to synthesize the first pulse light which has passed through the first optical path and the second pulse light which has passed through the second optical path are substantially optically conjugated.

According to a fifteenth aspect of the present invention, there is provided an illumination optical system including: a light source configured to emit pulse light, an optical system including (i) a division part configured to divide the pulse light into first pulse light and second pulse light, (ii) a delay optical system configured to guide the second pulse light to pass through a second optical path longer than a first optical path through which the first pulse light passes, and (iii) a synthesis part configured to synthesize the first and second pulse lights passing through the delay optical system; and an illumination system configured to guide the pulse light synthesized by the synthesis part to a mask on which a predetermined pattern is formed, wherein the illumination system includes an optical path switching part configured to switch an optical path of the synthesized pulse light and to sequentially guide the light to the masks provided in plural.

According to a sixteenth aspect of the present invention, there is provided an exposure device including: the illumination optical system described above; a projection optical system configured to irradiate an exposure target with a light emitted from the mask illuminated by the pulse light and to divisionally expose an exposure target; and a stage on which the exposure target is placeable.

According to a seventeenth aspect of the present invention, there is provided a method for manufacturing a flat panel display, including: exposing an exposure target using the exposure device described above; and developing the exposed exposure target.

### BRIEF DESCRIPTION OF THE DRAWINGS

FIG. 1 is a view schematically showing an external configuration of an exposure device of an embodiment.

FIG. 2 is a view schematically showing a configuration of an illumination module and a projection module of the embodiment.

FIG. 3 is a view showing a schematic configuration of the illumination module of the embodiment.

FIG. 4 is a view showing a schematic configuration of an optical modulation part of the embodiment.

FIG. 5 is a view showing a schematic configuration of a light source unit of the embodiment.

FIG. 6 is a view showing the configuration of the light source unit of the embodiment in detail.

FIG. 7 is a view showing an example of a polarization beam splitter of the embodiment.

FIG. 8 is a view showing an example of a configuration of a distribution part of the embodiment.

FIG. 9 is a view showing an example of a state of pulse light emitted from a light source part of the embodiment.

FIG. 10 is a view showing an example of the embodiment of a position where pulse light enters an optical fiber.

FIG. 11 is a view schematically showing a configuration of a retarder of the embodiment.

FIG. 12 is a view showing a first variant of the configuration of the retarder of the embodiment.

FIG. 13 is a view showing a second variant of the configuration of the retarder of the embodiment.

FIG. 14 is a view showing a third variant of the configuration of the retarder of the embodiment.

FIG. 15 is a view showing a fourth variant of the configuration of the retarder of the embodiment.

FIG. 16 is a view showing a fifth variant of the configuration of the retarder of the embodiment.

FIG. 17 is a view showing a sixth variant of the configuration of the retarder of the embodiment.

FIG. 18 is a view showing a variant of a distribution part of the embodiment.

FIG. 19 is a view showing a variant of correspondence between the light source unit and the illumination module of the embodiment.

FIG. 20 is a view showing a first variant of the light source unit of the embodiment.

FIG. 21 is a view showing a second variant of the light source unit of the embodiment.

FIG. 22 is a view showing a third variant of the light source unit of the embodiment.

FIG. 23 is a view showing a fourth variant of the light source unit of the embodiment.

### DESCRIPTION OF THE EMBODIMENTS

Hereinafter, an embodiment of the present invention will be described with reference to the accompanying drawings. The following detailed description of the present invention is exemplary only and not limiting. The same or similar reference signs are used throughout the drawings and the following detailed description.

### [Configuration of Exposure Device]

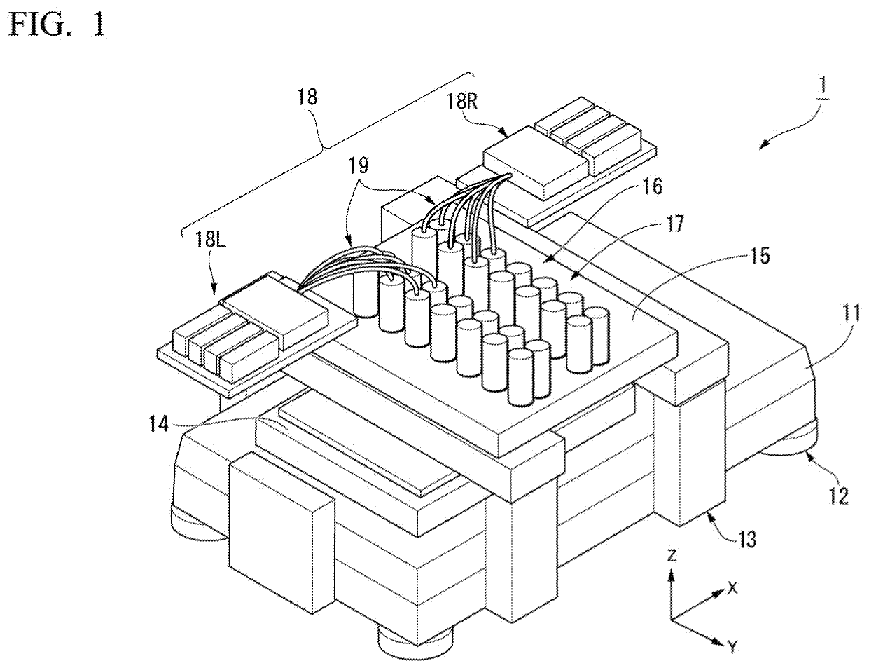

FIG. 1 is a view schematically showing an external configuration of an exposure device 1 of the embodiment. The exposure device 1 is a device configured to irradiate an exposure target with modulated light. In the specified embodiment, the exposure device 1 is a step and scan type projection exposure device, a so-called scanner using a rectangular (square) glass substrate used for a liquid crystal display device (flat panel display) or the like as an exposure target. The glass substrate, which is the exposure target, may be a substrate for a flat panel display having at least one side length of a diagonal length of 500 mm or more. The exposure target exposed by the exposure device 1 (for example, a substrate for a flat panel display) is provided as a product by being developed.

A device main body of the exposure device 1 has the same configuration as a device main body disclosed in, for example, US Patent Publication No. 2008/0030702.

The exposure device 1 includes a base 11, a vibration-isolated table 12, a main column 13, a stage 14, an optical surface plate 15, an illumination module 16, a projection module 17, a light source unit 18, an optical fiber 19, and an optical modulation part 20. The light source unit 18 includes a pair of light source units 18R and 18L as shown in FIG. 1. Hereinafter, the light source units 18R and 18L may be simply referred as the light source unit 18.

Hereinafter, a 3-dimensional orthogonal coordinate system in which a direction parallel to an optical axis direction of the projection module 17 configured to irradiate an exposure target with light modulated by the optical modulation part 20 is referred to as a Z-axis direction, and directions of a predetermined plane perpendicular to the Z axis are referred to as an X-axis direction and a Y-axis direction will be used as necessary for description. The X-axis direction and the Y-axis direction are directions perpendicular to (crossing) each other.

The base 11 is a base frame of the exposure device 1 and is installed on the vibration-isolated table 12. The base 11 supports the stage 14, on which an exposure target is placed, to be movable in the X-axis direction and the Y-axis direction.

The stage 14 supports an exposure target and accurately positions the exposure target with respect to a plurality of partial images of a circuit pattern projected via the projection module 17 in a scanning exposure, and the exposure target is driven in directions of 6 degrees of freedom (the above-mentioned X axis, Y axis and Z-axis directions, and Ox, Oy and Oz directions that are rotation directions of the axes). Further, the stage 14 is moved in the X-axis direction during scanning exposure and moved in the Y-axis direction when an exposure target region on the exposure target is changed. Further, a plurality of exposure target regions are formed on the exposure target. The exposure device 1 can expose the plurality of exposure target regions on one exposure target. While the configuration of the stage 14 is not particularly limited, a stage device with a so-called rough-micro motion configuration, which includes a gantry type 2-dimensional rough motion stage and a micro motion stage that is finely driven with respect to the 2-dimensional rough motion stage, can be used, as disclosed in US Patent Publication No. 2012/0057140. In this case, the exposure target can be moved by the rough motion stage in the directions of 3 degrees of freedom in the horizontal plane, and the exposure target can be moved minutely by the micro motion stage in the directions of 6 degrees of freedom.

The main column 13 supports the optical surface plate 15 above the stage 14 (in a positive direction of the Z axis). The optical surface plate 15 supports the illumination module 16, the projection module 17 and the optical modulation part 20.

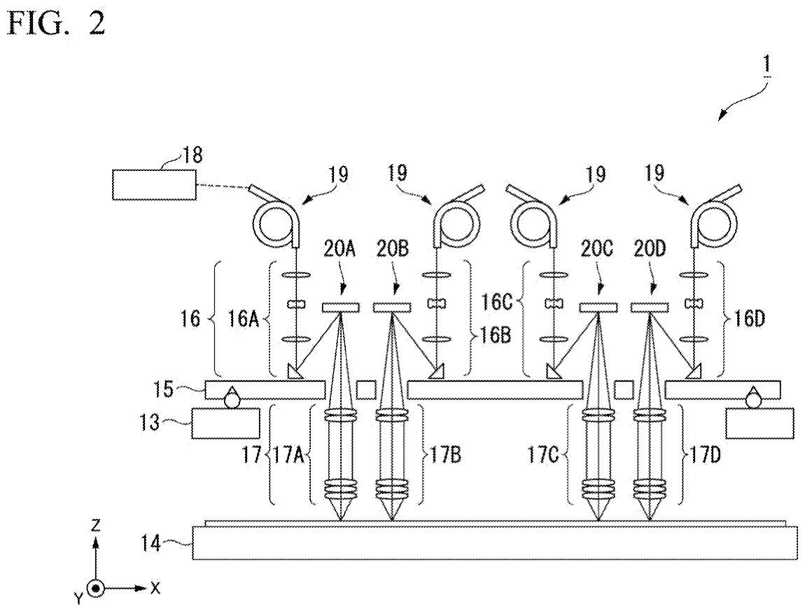

FIG. 2 is a view schematically showing configurations of the illumination module 16, the projection module 17 and the optical modulation part 20 of the embodiment.

The illumination module 16 is disposed above the optical surface plate 15, and connected to the light source unit 18 via the optical fiber 19. In the example of the embodiment, the illumination module 16 includes a first illumination module 16A, a second illumination module 16B, a third illumination module 16C and a fourth illumination module 16D. In the following description, when the first illumination module 16A to the fourth illumination module 16D are not distinguished, they are collectively referred to as the illumination module 16.

Each of the first illumination module 16A to the fourth illumination module 16D guides the light emitted from the light source unit 18 via the fiber 19 to each of a first optical modulation part 20A, a second optical modulation part 20B, a third optical modulation part 20C and a fourth optical modulation part 20D. The illumination module 16 illuminates the optical modulation part 20.

The optical modulation part 20, which will be described in more detail later, is controlled based on the circuit pattern to be transferred to the exposure target and modulates the illumination light from the illumination module. The light modulated by the optical modulation part 20 is guided to the projection module 17. The first optical modulation part 20A to the fourth optical modulation part 20D are disposed at different positions on the XY plane. In the following description, when the first optical modulation part 20A to the fourth optical modulation part 20D are not distinguished, they are collectively referred to as the optical modulation part 20.

The projection module 17 is disposed below the optical surface plate 15, and irradiates the exposure target placed on the stage 14 with the light modulated by a spatial light modulator 201. The projection module forms an image of the light modulated by the optical modulation part 20 on the exposure target and exposes the exposure target. In other words, the projection module projects the pattern on the optical modulation part 20 to the exposure target. In the example of the embodiment, the projection module 17 includes a first projection module 17A to a fourth projection module 17D corresponding to the first illumination module 16A to the fourth illumination module 16D and the first optical modulation part 20A to the fourth optical modulation part 20D. In the following description, when the first projection module 17A to the fourth projection module 17D are not distinguished, they are collectively referred to as the projection module 17.

A unit constituted by the first illumination module 16A, the first optical modulation part 20A and the first projection module 17A is referred to as a first exposure module. Similarly, a unit constituted by the second illumination module 16B, the second optical modulation part 20B and a second projection module 17B is referred to as a second exposure module. The exposure modules are provided at different positions on the XY plane, and can expose the patterns at different positions of the exposure target placed on the stage 14. By moving the stage 14 relatively in the X-axis direction, which is the scanning direction with respect to the exposure module, the entire surface of the exposure target or the entire surface of the exposure target region can be scanned and exposed.

Further, the projection module 17 is also referred to as a projection part. The projection module 17 (projection part) may be an unmagnification system that projects the pattern image on the optical modulation part 20 at the same magnification, or may be a spreading system or a reduction system. In addition, the projection module 17 is preferably constituted by one or two types of glass (especially quartz or fluorite).

The exposure device 1 includes a position measurement part (not shown) constituted by an interferometer, an encoder, and the like, in addition to the above-mentioned parts, and measures a relative position of the stage 14 with respect to the optical surface plate 15. The exposure device 1 includes an auto focus (AF) part (not shown) configured to measure a position of the stage 14 or the exposure target on the stage 14 in the Z-axis direction, in addition to the above-mentioned parts. Further, the exposure device 1 includes an alignment part (not shown) configured to measure a relative position of the patterns when another pattern overlaps the already exposed pattern on the exposure target and is exposed. The AF part and/or the alignment part may be a configuration of a through the lens (TTL) configured to perform measurement via the projection module.

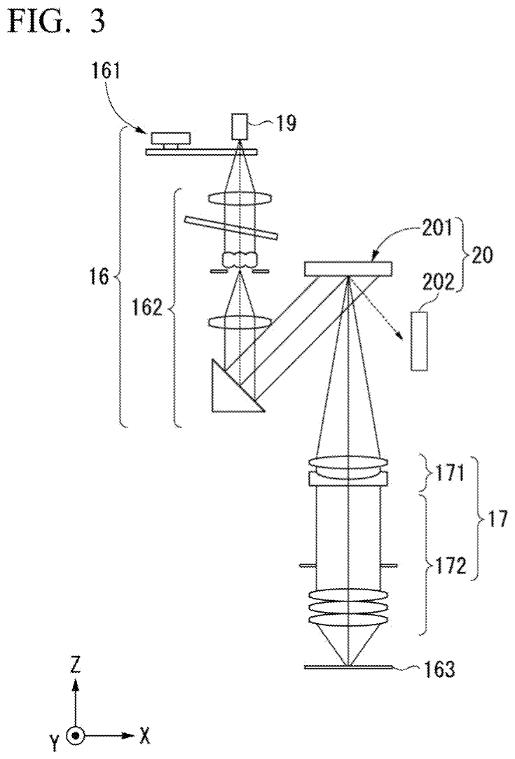

FIG. 3 is a view schematically showing a configuration of the exposure module of the embodiment. Taking the first exposure module as an example, an example of specific configurations of the illumination module 16, the optical modulation part 20 and the projection module 17 will be described.

The illumination module 16 includes a module shutter 161 and an illumination optical system 162. The module shutter 161 switches whether the pulse light supplied from the optical fiber 19 is guided to the illumination optical system 162.

The illumination optical system 162 substantially illuminates the optical modulation part 20 uniform with the pulse light supplied from the optical fiber 19 by emitting light to the optical modulation part 20 via a collimator lens, a fly eye lens, a condenser lens, or the like. The fly-eye lens wavefront-divides the pulse light entering the fly-eye lens, and the condenser lens superimposes the wavefront-divided light onto the light modulation part. Further, the illumination optical system 162 may include a rod integrator, instead of the fly eye lens.

The optical modulation part 20 includes a mask. The mask may be a photomask or may be a spatial light modulator (SLM).

Hereinafter, the case in which the mask is the spatial light modulator will be described.

The optical modulation part 20 includes the spatial light modulator 201 and an off light absorption plate 202. The spatial light modulator 201 includes a liquid crystal device, a digital mirror device (digital micromirror device, DMD), a magneto optic spatial light modulator (MOSLM), or the like. The spatial light modulator 201 may be of a reflective type that reflects the illumination light from the illumination optical system 162, a transmissive type that transmits the illumination light, or a diffractive type that diffracts the illumination light. The spatial light modulator 201 can spatially and temporally modulate illumination light.

Hereinafter, the case in which the spatial light modulator 201 is constituted by the digital micromirror device (DMD) will be described exemplarily.

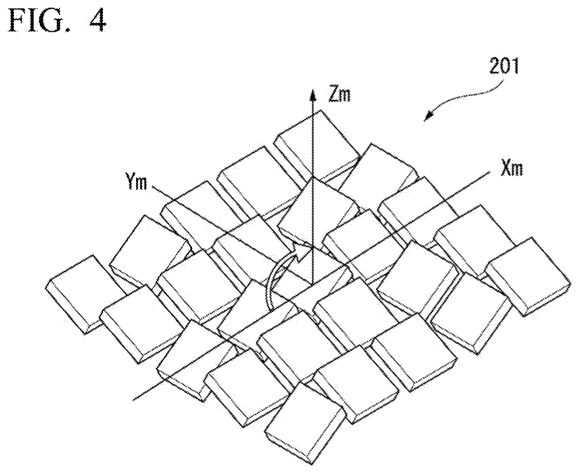

FIG. 4 is a view schematically showing a configuration of the spatial light modulator 201 of the embodiment. In FIG. 4, description will be performed using a 3-dimensional orthogonal coordinate system of Xm axis·Ym axis·Zm axis. The spatial light modulator 201 includes a plurality of micromirrors arranged in an XmYm plane. The micromirror constitutes an element (pixel) of the spatial light modulator 201. The spatial light modulator 201 can change the inclination angle around the Xm axis and around the Ym axis. The spatial light modulator 201, for example, becomes an ON state by tilting around the Ym axis, and becomes an OFF state by tilting around the Xm axis.

The spatial light modulator 201 controls the reflected direction of the incident light for each element by switching the micromirror's inclination angle for each micromirror. As an example, the digital micromirror device of the spatial light modulator 201 has a pixel number of about 4 Mpixel and can switch between the ON state and the OFF state of the micromirror at a period of about 10 kHz.

The spatial light modulator 201 is individually controlled by each of the elements with a predetermined time interval. When the spatial light modulator 201 is the DMD, the element is a micromirror and the predetermined time interval is a period when the micromirror are switched between the ON state and the OFF state (for example, a period of 10 kHz).

Returning to FIG. 3, the off light absorption plate 202 absorbs the light (off light) emitted (reflected) from the element in which the spatial light modulator 201 is in an OFF state. The light emitted from the element in which the spatial light modulator 201 is in an ON state is guided to the projection module 17.

The projection module 17 projects the light emitted from the element in which the spatial light modulator 201 is in the ON state on the exposure target. The projection module includes a magnification adjuster 171 and a focus adjuster 172. The light modulated by the spatial light modulator 201 (modulated light) enters the magnification adjuster 171.

The magnification adjuster 171 adjusts magnification of an image on a focal surface 163 of the modulated light emitted from spatial light modulator 201, i.e. a surface of the exposure target, by driving some of the lenses in an optical axis direction.

The focus adjuster 172 adjusts an imaging position, i.e., a focus such that the modulated light emitted from the spatial light modulator 201 forms an image on a surface of the exposure target measured by the above-mentioned AF part by driving the entire lens group in the optical axis direction.

The projection module 17 projects only the image of the light emitted from the element in which spatial light modulator is in the ON state onto the surface of the exposure target. For this reason, the projection module 17 can project and expose an image of the pattern formed by the ON element of the spatial light modulator 201 onto the surface of the exposure target. That is, the projection module 17 can form the spatially modulated light on the surface of the exposure target. In addition, since the spatial light modulator 201 can switch between the ON state and the OFF state of the micromirror at the predetermined period (frequency) as mentioned above, the projection module 17 forms the temporally modulated light on the surface of the exposure target.

That is, the exposure device 1 performs exposure by changing the substantial pupil state at an arbitrary exposure position.

The illumination module 16 is also referred to as an illumination system. The illumination module 16 (illumination system) illuminates the spatial light modulator 201 (spatial light modulation element) with the pulse light distributed by a distribution part 184.

In the related art, speckles may occur when a high coherence single pulse laser is used to illuminate a spatial light modulation element with an integrator (for example, a fly eye lens), and in some cases, the quality of the circuit pattern was affected by the spatial light modulation element transferred to the substrate. Further, the laser light source with high coherence is referred to as pulse light that illuminates the spatial light modulation element using an optical integrator with the emitted light of 1 pulse, and generates dispersion exceeding 20% as an intensity distribution in the plane or the pupil where the speckles are problems when it is exposed by the spatial light modulation element pattern.

The exposure device 1 of the embodiment includes the light source unit 18 that can reduce the speckles and improve quality of the circuit pattern transferred onto the substrate. Hereinafter, the light source unit 18 of the embodiment will be described.

### [Configuration of Light Source Unit]

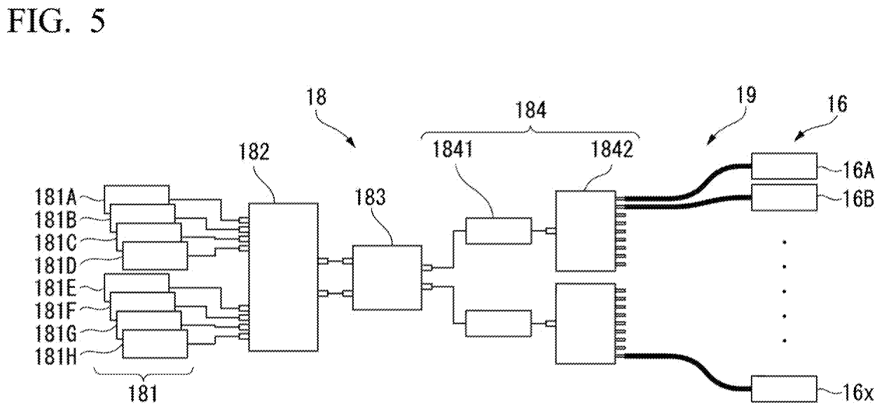

FIG. 5 is a view schematically showing a configuration of the light source unit 18 of the embodiment. The light source unit 18 includes a light source part 181, a synthesis part 182, a retarder 183 and the distribution part 184.

The light source part 181 emits light with a predetermined wavelength. The light emitted from the light source part 181 may be continuous light or pulse light. Hereinafter, the case in which the light source part 181 emits pulse light will be described.

Further, when the light source part 181 emits continuous light, by converting the continuous light into the pulse light through switching of a shutter (not shown), modulation by an acoustooptic modulator (not shown), or the like, the light emitted from the light source part 181 may be substantial pulse light.

The light source part 181 includes a first light source part 181A to an eighth light source part 181H. The first light source part 181A to the eighth light source part 181H each includes a seed light source and emits pulse light with a predetermined wavelength.

As an example, the light source part 181 includes a fiber, an excitation laser diode (LD) and a wavelength conversion crystal (none is shown). The light source part 181 causes the laser amplified by the fiber and excitation LD to enter the wavelength conversion crystal and emit 3rd harmonic pulse light.

Further, the light source provided in the light source part 181 may be a laser light source (for example, a fiber laser) with high coherence, or may be a UV-LD. In addition, light source part 181 may be a laser light source with a wavelength of emitted light of 360 nm or less.

The synthesis part 182 synthesizes the pulse light emitted from each of the plurality of laser light sources included in the light source part 181. The synthesis part 182 generates the pulse light with great intensity (great energy) by synthesizing the pulse light. The synthesis part 182 emits the synthesized pulse light to the retarder 183.

The retarder 183 performs repetition of division and synthesis of the pulse light emitted from the synthesis part 182, and changes distribution of a time axis of the pulse light by combining the pulse lights with different delay times. The retarder 183 emits the pulse light in which the time axis distribution has been changed to the distribution part 184.

Further, the retarder 183 is also referred to as a delay optical system. The retarder 183 (delay optical system) delays some of the pulse light. In addition, the retarder 183 (delay optical system) divides some of the pulse light to guide it to the delay optical path, and synthesizes some of the pulse light guided to the delay optical path with the other of the divided pulse light so as to change time characteristics of the pulse light.

The distribution part 184 distributes the pulse light emitted from the retarder 183 to the plurality of optical fibers 19. That is, the distribution part 184 distributes the pulse light to the plurality of exposure modules. For example, the distribution part 184 guides pulse light of first pulse from the retarder 183 to a first exposure module, and guides pulse light of second pulse to a second exposure module. The distribution part 184 can also be said to be a switching part because it changes the exposure module to which each pulse are guided.

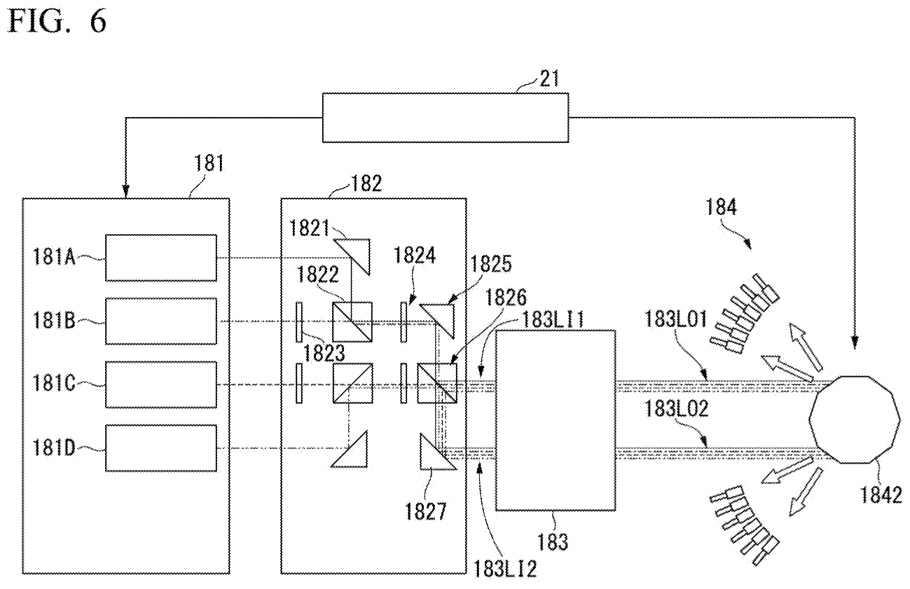

FIG. 6 is a view showing the configuration of the light source unit 18 of the embodiment in detail. In FIG. 6, in the first light source part 181A to the eighth light source part 181H, the first light source part 181A to the fourth light source part 181D are partially shown. Portions of the fifth light source part 181E to the eighth light source part 181H have the same configurations as the portions of the first light source part 181A to the fourth light source part 181D, and thus, description thereof will be omitted.

The synthesis part 182 includes a prism mirror 1821, a polarization beam splitter 1822, a wave plate 1823, a wave plate 1824, a prism mirror 1825, a polarization beam splitter 1826 and a prism mirror 1827. The prism mirror 1821 guides the pulse light (s-polarized light) emitted from the first light source part 181A to the polarization beam splitter 1822. The wave plate 1823 changes a polarization state of the pulse light (s-polarized light) emitted from a second light source part 181B and guides the pulse light (p-polarized light) to the polarization beam splitter 1822.

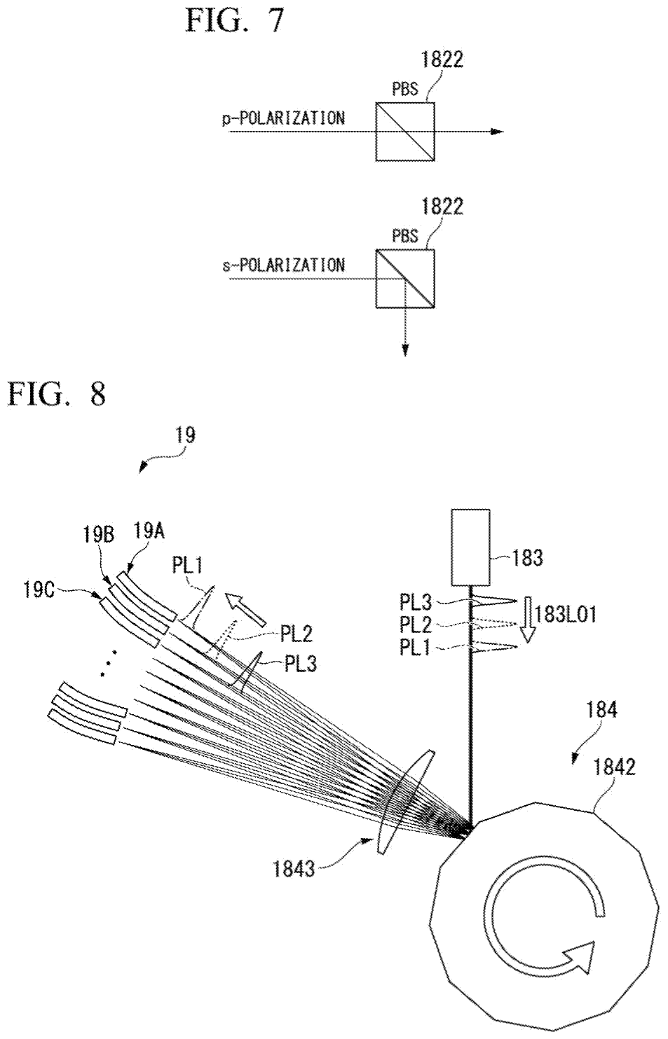

FIG. 7 is a view showing an example of the polarization beam splitter 1822 of the embodiment. The polarization beam splitter 1822 transmits the pulse light when the entering pulse light is p-polarized light. The polarization beam splitter 1822 reflects the pulse light when the entering pulse light is s-polarized light.

Returning to FIG. 6, the polarization beam splitter 1822 reflects the pulse light (s-polarized light) reflected by the prism mirror 1821 and guides it to the wave plate 1824. In addition, the polarization beam splitter 1822 transmits the pulse light (p-polarized light) passing through the wave plate 1823 and guides it to the wave plate 1824. That is, the pulse light emitted from the first light source part 181A enters the wave plate 1824 as s-polarized light (0-degree linear polarized light), and the pulse light emitted from the second light source part 181B enters the wave plate 1824 as p-polarized light (90-degree linear polarized light). That is, two types of pulse lights whose polarization directions are orthogonal to each other are synthesized at a rate of 50% each and both enter the wave plate 1824.

The wave plate 1824 rotates the polarization direction of the entering pulse light. The wave plate 1824 rotates the polarization direction of the entering s-polarized light (0-degree linear polarized light) to make +45-degree linear polarized light, and rotates the polarization direction of the entering p-polarized light (90-degree linear polarized light) to make −45-degree linear polarized light.

Two types of pulse lights, i.e., the +45-degree linear polarized light and the −45-degree linear polarized light are emitted from the wave plate 1824. The two types of pulse lights emitted from the wave plate 1824 are reflected by the prism mirror 1825 and guided to the polarization beam splitter 1826.

The polarization beam splitter 1826 emits the entering pulse light to the retarder 183. Here, the +45-degree linear polarized light from the first light source part 181A and the −45-degree linear polarized light from the second light source part 181B enter the polarization beam splitter 1826. The polarization beam splitter 1826 reflects s-polarized light elements of the entering pulse light, i.e., s-polarized light of the +45-degree linear polarized light and s-polarized light of the −45-degree linear polarized light and emits them to the retarder 183. The polarization beam splitter 1826 transmits p-polarized light elements of the entering pulse light, i.e., p-polarized light of the +45-degree linear polarized light and the p-polarized light of the −45-degree linear polarized light and emits them to the retarder 183 via the prism mirror 1827.

That is, the polarization beam splitter 1822 coaxially synthesizes the pulse light emitted from the first light source part 181A and the pulse light emitted from the second light source part 181B and emits the synthesized pulse light to the retarder 183. Further, while it is assumed that the polarization beam splitter 1822 coaxially synthesizes the pulse light emitted from the first light source part 181A and the pulse light emitted from the second light source part 181B, each of the optical axes may be slightly shifted, i.e., may be synthesized paraxially. In a case the polarization beam splitter 1822 is a plate type, when the pulse light of the p-polarized light passes through the polarization beam splitter 1822, the optical axis thereof is slightly moved in parallel direction. This is caused by the slight refraction of the pulse light passing through the PBS due to the refractive index of the PBS, and the light having an optical axis slightly shifted in parallel direction from the optical axis when entering the PBS is emitted from the PBS. By paraxial synthesis, the energy (power) per unit area of the pulse light hitting the optical element, that is, the energy density can be dispersed. As a result, deterioration including deformation or the like of the optical element can be suppressed.

Similarly, the synthesis part 182 coaxially synthesizes the pulse light emitted from the third light source part 181C and the pulse light emitted from the fourth light source part 181D and emits the synthesized pulse light to the retarder 183.

In other words, the light source unit 18 includes a synthesis device. The synthesis part 182 is an example of the synthesis device. The synthesis device synthesizes the pulse lights emitted from the plurality of light sources, respectively. In the following description, the pulse light emitted from the polarization beam splitter 1826 to the retarder 183 is also referred to as retarder incident light 183LI. In the retarder incident light 183LI, the pulse light emitted from the polarization beam splitter 1826 to the retarder 183 without going through the prism mirror 1827 is also referred to as first retarder incident light 183LI1, and the pulse light emitted from the polarization beam splitter 1826 to the retarder 183 via the prism mirror 1827 is also referred to as second retarder incident light 183LI2.

That is, the two types of pulse lights of the first retarder incident light 183LI1 and the second retarder incident light 183LI2 emitted from the light source part 181, which are different from each other, enter the retarder 183. As described above, both the first retarder incident light 183LI1 and the second retarder incident light 183LI2 are light obtained by coaxially (or substantially coaxially) synthesizing the pulse lights emitted from each of the light sources of the first light source part 181A to the fourth light source part 184D.

Further, while the first retarder incident light 183LI1 and the second retarder incident light 183LI2 will be described as entering the retarder 183, there is no limitation thereto. The pulse light entering the retarder 183 may be only the first retarder incident light 183LI1.

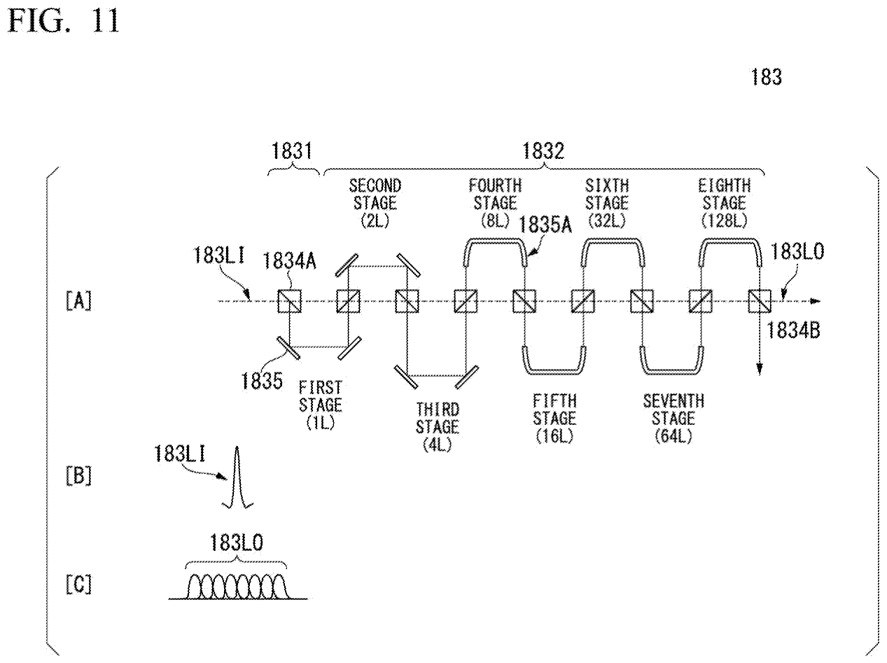

As shown in FIG. 11 or the like, the retarder 183 includes an input stage beam splitter 1834A. The input stage beam splitter 1834A synthesizes and divides the first retarder incident light 18311 and the second retarder incident light 183LI2. Each of the divided pulse lights enters a delay stage 1832.

Further, although the synthesis and division of the beam are described as being performed by a beam splitter using polarization, the present invention is not limited to this, and a half mirror, a half prism, or the like, may be used.

The delay stage 1832 has a delay optical path, and changes the time axis distribution of each of the first retarder incident light 183LI1 and the second retarder incident light 183LI2. The delay stage 1832 outputs the pulse light in which the time axis distribution has been changed to the distribution part 184 as a first retarder outgoing beam 183LO1 and a second retarder outgoing beam 183LO2.

In other words, the retarder 183 (delay optical system) guides the second pulse light to follow a second optical path longer than the first optical path along which the first pulse light follows. The retarder 183 (delay optical system) divides some of the synthesized pulse light by the synthesis part 182 (synthesis device) and guides it to the second optical path.

FIG. 8 is a view showing an example of a configuration of the distribution part 184 of the embodiment. The distribution part 184 includes a rotation switch 1841 and a distributor 1842. Further, in FIG. 8, the first retarder outgoing beam 183LO1 will be described, and description of the second retarder outgoing beam 183LO2 will be omitted. In addition, in FIG. 8, illustration of the rotation switch 1841 is omitted.

The distributor 1842 selects the optical fiber 19, into which the pulse light enters, from the plurality of optical fibers 19. Specifically, the distributor 1842 includes a polygon mirror device rotated at a predetermined rotation number. The polygon mirror device reflects the pulse light entering from the retarder 183 in a direction according to a rotation angular velocity.

As the polygon mirror device is rotated, an angle of the reflecting surface of the polygon mirror device with respect to the pulse light entering from the retarder 183 is changed. Accordingly, the destination of the pulse light entering the retarder 183 and reflected by the reflecting surface of the polygon mirror device changes with time.

The rotation angular velocity of the polygon mirror device is determined according to a time interval of a light emission timing of the pulse light. For example, when the pulse light enters the polygon mirror device in sequence of a first pulse PL1, a second pulse PL2 and a third pulse PL3, the first pulse PL1 enters a first optical fiber 19A, the second pulse PL2 enters a second optical fiber 19B, and the third pulse PL3 enters a third optical fiber 19C.

That is, the distribution part 184 distributes the pulse light emitted from the retarder 183 to each of the plurality of optical fibers 19. That is, the distribution part 184 can switch the optical fiber 19 that receives the pulse light emitted from the retarder 183 every time.

The rotation switch 1841 is provided between the retarder 183 and the distributor 1842 while not shown in FIG. 8. The rotation switch 1841 guides the pulse light emitted from the retarder 183 to a first surface of the polygon mirror device at a time interval T1 (for example, between a time t1 and a time t2), and guides the pulse light to a second surface of the polygon mirror device at a time interval T2 (for example, between the time t2 and a time t3). Since the rotation switch 1841 is constantly rotated, in a time interval T3 (for example, between the time t3 and a time t4), a third surface of the polygon mirror device moves to a place where the first surface was originally located. In a time interval T4 (for example, between the time t4 and a time t5), similarly, a fourth surface of the polygon mirror device moves to a place located on a second surface. That is, the first surface at the time interval T1 and the third surface at the time interval T3 have the same angle with respect to the pulse light emitted from the retarder 183. In addition, the second surface at the time interval T2 and the fourth surface at the time interval T4 have the same angle with respect to the pulse light emitted from the retarder 183. That is, the rotation switch 1841 changes the plane on the polygon mirror that guides the pulse light at every certain time interval. The pulse light reflected by the first surface in the time interval T1 enters, for example, in sequence from the first optical fiber 19A to the fifth optical fiber 19E. The pulse light reflected by the second surface in the time interval T2 enters, for example, in sequence from the sixth optical fiber 19F to a tenth optical fiber 19J, which are not shown. The pulse light reflected by the third surface in the time interval T3 enters in sequence from the first optical fiber 19A to the fifth optical fiber 19E. The pulse light reflected by the fourth surface in the time interval T4 enters, for example, in sequence from the sixth optical fiber 19F to the tenth optical fiber 19J, which are not shown. In this way, the rotation switch 1841 changes the plane on the polygon mirror that guides the pulse light every certain time interval.

Further, in the distribution part 184, an optical path switching part and a light guide part may be provided at positions where the emission position from which the pulse light is emitted from the optical path switching part (for example, the polygon mirror device) and an incidence position of the pulse light of the light guide part (for example, the optical fiber 19) are optically almost conjugated.

In addition, the distribution part 184 may include a lens 1843 configured to condense the pulse light reflected by the polygon mirror device to a position of an incidence end of each of the optical fibers 19, and further, a relay lens may be used to conjugate the reflecting surface of the polygon mirror device and the incident surface of the optical fiber 19. In other words, the light source unit 18 may include a relay lens configured to substantially optically conjugate the emission position where the pulse light is emitted from the optical path switching part and the incidence position of the pulse light of the light guide part between the optical path switching part (for example, a polygon mirror device) and the light guide part (for example, the optical fiber 19).

In addition, instead of the polygon mirror device, the distribution part 184 may use an optical path change due to a galvanometer mirror or an acoustooptic modulator (AOM) to slightly oscillate the emission direction of the pulse light.

The optical fiber 19 supplies the pulse light distributed by the distributor 1842 to the illumination module 16.

It can be said that the plurality of optical fibers 19 are configured to guide the first pulse light and the second pulse light emitted from the different light source parts 181 to the one spatial light modulator 201.

The first optical transmission part of the plurality of optical transmission parts guides the first pulse light and the second pulse light to a first spatial light modulator among the plurality of provided spatial light modulators 201.

The second optical transmission part of the plurality of optical transmission parts guides the first pulse light and the second pulse light to a second spatial light modulator among the plurality of provided spatial light modulators 201.

In addition, in the light source unit 18, a light source and an optical path switching part may be provided at a position where an emission position of pulse light of the light source (for example, the light source part 181) and an incidence position where the pulse light enters the optical path switching part (for example, the distributor 1842) are substantially optically conjugated.

According to the light source unit 18 configured as above, since the emission position of the pulse light of the light source part 181 and the incidence position where the pulse light enters the distributor 1842 are conjugated, the incidence position where the pulse light enters the distributor 1842 can be easily adjusted by adjusting the emission position of the pulse light of the light source part 181. Accordingly, according to the light source unit 18 configured as above, in an exchange work or a position adjustment work of the light source part 181, the incidence position where the pulse light enters the distributor 1842 can be easily adjusted.

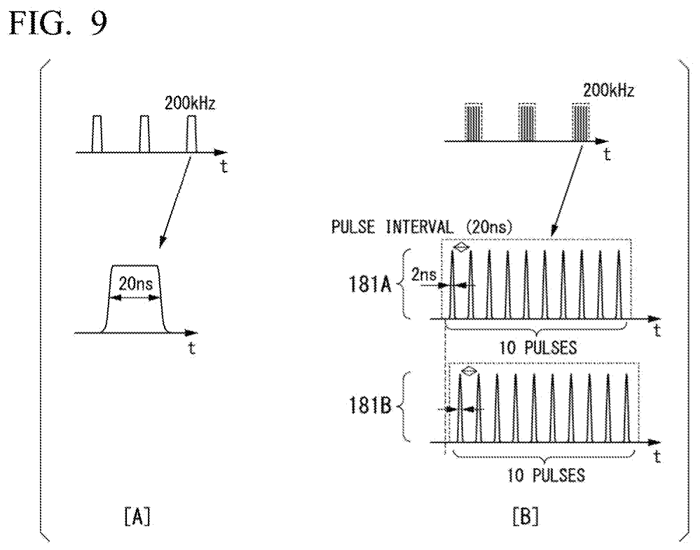

Returning to FIG. 6, a controller 21 controls a state of the pulse light emitted from the light source part 181. An example of the pulse light emitted from the light source part 181 will be described with reference to FIG. 9.

### [Operation of Light Source Unit 18]

FIG. 9 is a view showing an example of a state of the pulse light emitted from the light source part 181 of the embodiment. Part (A) of FIG. 9 shows an example of a state of the pulse light emitted from the light source part in the related art. The light source part in the related art emits pulse light with a pulse width of 20 ns and a period of 200 kHz.

Part (B) of FIG. 9 shows an example of a state of the pulse light emitted from the light source part 181 of the embodiment. The light source part 181 of the embodiment emits group pulse light with a pulse width of 2 ns, a pulse interval of 20 ns, a pulse number of 10, and a period of 200 kHz.

Here, the light source part 181 of the embodiment causes the plurality of light source parts 181 to emit group pulse light at different timings. As an example, both the first light source part 181A and the second light source part 181B emit group pulse light with a pulse width of 2 ns, a pulse interval of 20 ns, a pulse number of 10, and a period of 200 kHz. The second light source part 181B emits the pulse light in a duration of a pulse interval of 20 ns of the group pulse light emitted from the first light source part 181A.

That is, the pulse light emission timing of the first light source part 181A and the pulse light emission timing of the second light source part 181B are shifted from each other.

As an example, while the first light source part 181A and the second light source part 181B have been described, emission timings of the first light source part 181A to the fourth light source part 181D may be shifted from each other.

That is, the light source unit 18 makes the state of the pulse light distributed by the distribution part 184 different from each other by differentiating the light emission timing of the pulse light from each other.

Specifically, as shown in part (B) of FIG. 9, the first light source part 181A emits first pulse light at a first time point. The second light source part 181B emits second pulse light at a second time point different from the first time point.

As described above, the illumination module 16 (illumination system) guides the first pulse light and the second pulse light to the spatial light modulator 201 and guides them to the spatial light modulator 201.

The second light source part 181B emits the second pulse light at the second time point when the time interval from the first time point is shorter than the predetermined time interval. The predetermined time interval is the period for switching the ON state and OFF state of the micromirror when the spatial light modulator 201 is the DMD.

The first light source part 181A continuously emits the first pulse light by a predetermined period. The second light source part 181B continuously emits the second pulse light by a predetermined period. The predetermined period is a period (for example, a period of 200 kHz) of the group pulse light shown in part (B) of FIG. 9. The continuous emission is emission as group pulse light with a predetermined pulse width (for example, a pulse width of 2 ns), a predetermined pulse interval (for example, a pulse interval of 20 ns), and a predetermined pulse number (for example, a pulse number of 10).

The second light source part 181B emits the second pulse light at the time during which the continuous first pulse light is emitted from the first light source part 181A. The time during which the continuous first pulse light is emitted from the first light source part 181A is a time (for example, 200 ns) during which one group pulse light of the first pulse light is emitted.

The first light source part 181A and the second light source part 181B continuously emit the first pulse light and the second pulse light by the predetermined period that is a time interval shorter than the predetermined time interval controlled by the device of the spatial light modulator 201. That is, an oscillation time interval (the above-mentioned predetermined period, for example, a period of 200 kHz) of the group pulse light is a time interval shorter than a predetermined time interval (for example, 10 kHz) individually controlled by a plurality of devices of the spatial light modulator 201.

According to the light source unit 18 configured as above, since the emission timings of the plurality of pulse lights are different from each other and the coherence of the pulse light is reduced, occurrence of speckles can be suppressed.

Further, the above-mentioned pulse light emission timing may be adjusted as the controller 21 controls the light source part 181. The first light source part 181A to the eighth light source part 181H, which are above-mentioned, each includes a seed light source, the controller controls each of the seed light sources, and thus, an oscillation timing of the pulse light for each of the light sources can be controlled. The controller 21 makes the states of the pulse lights on the spatial light modulators 201 different from each other by making the light emission timings of the plurality of pulse lights different from each other. The controller 21 is an example of the state changing part.

In addition, the above-mentioned pulse light emission timing may be set in advance in the light source part 181 without being controlled by the controller 21.

The light source part 181 of this embodiment may have different wavelengths of pulse lights emitted from each of the plurality of light source parts 181. As an example, the central wavelength of the pulse light of the plurality of light source parts 181 is made different by several picometers to several tens of picometers. An allowance value of the central wavelength deviation amount, which is made different for each light source part 181, is determined, for example, by the chromatic aberration generated in the projection module due to the deviation amount, as an example. For example, if the allowance value is 100 pm and the number of light sources is 5, each light source is shifted evenly by 20 pm. Further, the amount of the shift may not be uniform. In other words, the central wavelength for each of the light source part 181 is shifted to the extent that chromatic aberration does not cause exposure defects. As an example, the light source part 181 changes the wavelength of the emitted pulse light according to changes in the operating environment temperature. The plurality of light source parts 181 make the wavelengths of the pulse lights different from each other by making the operation environment temperatures different from each other.

Further, provided that a wavelength difference of a central wavelength between the first pulse light and the second pulse light is λ, chromatic aberration of the projection optical system occurred due to the wavelength difference λ is Δ and a numerical aperture of the projection optical system is NA, it satisfies λ>Δ×(NA\hat{ }2).

Further, the light source unit 18 may include a temperature control device (a warming device or a cooling device, none is shown) configured to change an operation environment temperature of the light source part 181. In addition, the temperature control device may have a configuration of changing an operation environment temperature of the light source part 181 under control of the controller 21. In this case, the controller 21 controls the operation environment temperature of the plurality of light source parts 181 so that the wavelengths of the pulse lights emitted from the plurality of light source parts 181 are different from each other.

The light source unit 18 positively and periodically changes the temperature of the seed light to change the wavelength periodically, and it is also possible to change the wavelength periodically within a certain range.

The light source unit 18 may include a wavelength filter device (not shown) that enables transmission of the pulse light with a partial wavelength band of the wavelength band emitted from the light source part 181. In addition, the wavelength filter device may be configured to change the wavelength of the transmitted pulse light on the basis of the control of the controller 21. In this case, the controller 21 controls the wavelength band transmitted by the wavelength filter device to be different from each other for the plurality of light source parts 181, so that the wavelengths of the pulse lights emitted from the plurality of light source parts 181 are different from each other.

The light source unit 18 is an example of the state changing part. The light source unit 18 (state changing part) varies the states of the pulse light distributed by the distribution part 184 by varying the wavelengths of the plurality of pulse lights.

For example, the wavelength of the pulse light emitted from the first light source part 181A is different from the wavelength of the pulse light emitted from the second light source part 181B. The first light source part 181A emits the first pulse light having a wavelength different from the second pulse light emitted from the second light source part 181B.

The light source unit 18 may include a wavelength measuring device (not shown) configured to measure a wavelength of the emitted pulse light. The controller 21 controls the wavelength of the pulse light emitted from the light source part 181 on the basis of the measured result of the wavelength of the pulse light by the wavelength measuring device.

In other words, the controller 21 makes the states of the pulse lights on the spatial light modulators 201 different from each other by making the wavelengths of the plurality of pulse lights different from each other. The controller 21 is an example of the state changing part.

According to the light source unit 18 configured as above, since the wavelengths of the plurality of pulse lights are different from each other and the coherence of the pulse light is reduced, occurrence of speckles can be suppressed.

While the case in which the wavelength of the first pulse light and the wavelength of the second pulse light are different from each other has been described, there is not limitation thereto. The phase state of the first pulse light and the phase state of the second pulse light may be different from each other. In this case, the illumination system may have a phase changing part configured to change the phase state of at least one of the first pulse light and the second pulse light.

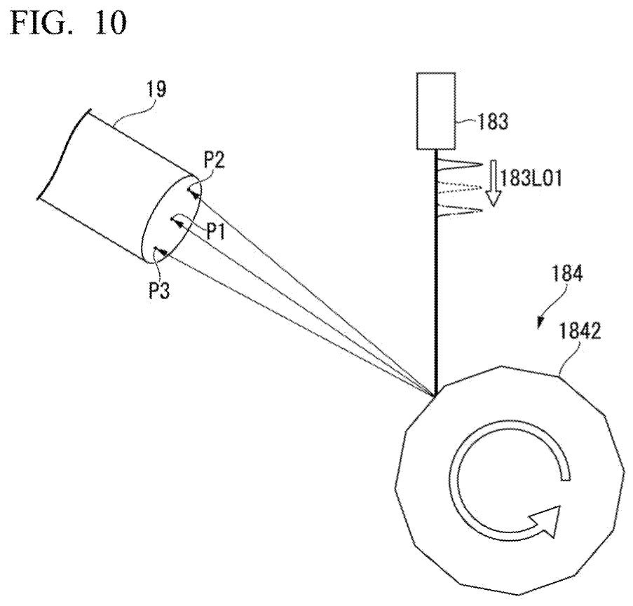

Returning to FIG. 6, the controller 21 controls a position where the pulse light enters the optical fiber 19 by controlling the distribution part 184. An example of control of a position where the pulse light enters the optical fiber 19 will be described with reference to FIG. 10.

FIG. 10 is a view showing an example of a position where the pulse light of the embodiment enters the optical fiber 19.

As described above, the pulse light (for example, the first retarder outgoing beam 183LO1) enters the distributor 1842 (for example, polygon mirror device) from the retarder 183. The first retarder outgoing beam 183LO1 entering the distributor 1842 is reflected in a direction based on the incidence angle to the polygon mirror device and the angle of the reflecting mirror at the incident timing. The angle of the reflecting mirror at the incident timing changes as the rotation speed (angular velocity) of the polygon mirror device changes.

For example, when the rotation speed of the distributor 1842 is a predetermined angular velocity, the first retarder outgoing beam 183LO1 reflected by the distributor 1842 enters a position P1 of the optical fiber 19. When a rotation speed of the distributor 1842 is slower than a predetermined angular velocity, the first retarder outgoing beam 183LO1 reflected by the distributor 1842 enters a position P2 of the optical fiber 19. When a rotation speed of the distributor 1842 is faster than a predetermined angular velocity, the first retarder outgoing beam 183LO1 reflected by the distributor 1842 enters a position P3 of the optical fiber 19.

Here, although the change in the position of the light entering the fiber is described, for example, the reflecting surface of the polygon mirror device and the fiber incidence port may be conjugated by the lens. In other words, the distribution part 184 may have an optical path switching part and a light guide part, which are provided at a position where the emission position where the pulse light is emitted from the optical path switching part (for example, the polygon mirror device) and the incidence position of the pulse light of the light guide part (for example, the optical fiber 19) are substantially optically conjugated. According to the light source unit 18 configured as above, the incidence position of the fiber is almost unchanged, but the incidence angle to the fiber can be changed.

That is, by changing the rotation speed (angular velocity) of the polygon mirror device, the incident position and the incidence angle of the pulse light to the optical fiber 19 change.

When the incidence position and the incidence angle of the optical fiber 19 of the pulse light are changed, a route of the pulse light guided into the optical fiber 19 is changed, and temporal characteristics of the pulse light are changed.

The controller 21 changes the rotation speed of the polygon mirror device to change the route of the pulse light guided through the optical fiber 19, thereby changing the temporal characteristics of the pulse light emitted from the illumination module 16.

That is, the light source unit 18 makes the distribution timing of the pulse light by the distribution part 184 different, thereby making the state of the pulse light distributed by the distribution part 184 different.

For example, the illumination system includes an optical transmission part configured to guide first pulse light and second pulse light to the spatial light modulator 201. The above-mentioned optical fiber 19 is an example of the optical transmission part. The phase changing part adjusts incidence angles of the first pulse light and the second pulse light entering the optical transmission part (for example, the optical fiber 19). The polygon mirror device, the rotation speed (angular velocity) of which is changed, is an example of the phase changing part.

In other words, the illumination system includes an optical path switching part. The optical path switching part switches the optical path of the synthesized pulse light and guides it to the plurality of provided masks in sequence. The polygon mirror device is an example of the optical path switching part. Further, as described above, the mask may be a photomask or may be a spatial light modulator.

In the case in which the illumination system has the optical path switching part configured to switch the optical path of the synthesized pulse light and guide it to the plurality of provided masks in sequence, the controller 21 makes the states of the pulse light on the spatial light modulator 201 different from each other by making the distribution timing of the pulse light by the optical path switching part different. The distribution timing control of the pulse light by the optical path switching part by the controller 21 is an example of the state changing part.

That is, the illumination system has an optical path switching machine configured to switch optical paths of the first pulse light and the second pulse light sequentially oscillated from the first light source part 181A and the second light source part 181B and to guide the lights to the plurality of provided optical transmission parts (for example, the optical fibers 19) in sequence. The above-mentioned polygon mirror device is an example of the optical path switching machine.

The optical path switching machine has reflecting surfaces configured to reflect first pulse light and second pulse light, and changes incidence angles of the reflecting surfaces with respect to the first pulse light and the second pulse light and switches the optical path.

The phase changing part controls the optical path switching machine to adjust the incidence angles of the first pulse light and the second pulse light entering the optical transmission part.

Further, the phase changing part may have a diffusion plate configured to diffuse light entering the spatial light modulator 201. In addition, the phase changing part may cause a phase change by shaking the optical fiber 19 itself.

As described above, the exposure device 1 includes a projection optical system configured to divisionally expose the substrate by irradiating the substrate with the light emitted from each of the plurality of spatial light modulators 201 illuminated by the first pulse light and the second pulse light.

According to the light source unit 18 configured as above, since the temporal characteristics of the plurality of pulse lights are different from each other and the coherence of the pulse light is reduced, occurrence of speckles can be suppressed.

Further, a diffusion plate may be placed just before the incidence end of each of the fibers 19. The diffusion plate can diffuse the pulse light and change the incidence position and the incidence angle of the pulse light to the fiber, so that the phase and the wave surface of the pulse light can be changed. The diffused pulse lights overlap each other and are averaged. For this reason, it is possible to change a phase, a wave surface, intensity, and the like, for each pulse light entering the same fiber 19.

Further, the diffusion plate may include a mechanism configured to perform rotational movement and/or translational movement. The mechanism can change a diffusion state of the pulse light and can change an incidence position or an incidence angle of the pulse light to the fiber by changing a position on the diffusion plate where the pulse light passes. The mechanism can change the phase or the wave surface of the pulse lights when the diffusion plate is moved after first pulse passes and before second pulse passes. In this way, the movement of the phase or the wave surface diffusion plate for each pulse light may be performed for each pulse, or may be performed for multiple pulses. In addition, the diffusion plate may be placed for a plurality of fibers instead of for each of the fibers 19.

Further, while the incidence position of the pulse light to the optical fiber 19 is changed by changing a rotation speed (angular velocity) of the polygon mirror device, there is no limitation thereto. The rotation speed of the polygon mirror device may be fixed, the incident end of the optical fiber 19 may be moved, and the position where the pulse light enters may be shifted. Further, the incidence end of the optical fiber 19 may be moved while changing a rotation speed of the polygon mirror device.

Further, the diffusion plate may be provided on an emission end of the optical fiber 19. In addition, the diffusion plate may be provided on an emission end of each of the light sources.

### [Configuration of Retarder 183]

As described above, the retarder 183 emits a retarder outgoing beam 183LO, a state of the pulse light of which is changed, by dividing and synthesizing the retarder incident light 183LI.

Specifically, the retarder 183 divides the entered pulse light into multiple (for example, two) and makes the optical path length of one of the divided pulse lights longer than the optical path length of the other pulse light, thereby causing a delay equivalent to the pulse width in the pulse light. The retarder 183 synthesizes the divided pulse lights to output pulse light whose state is changed for the entered pulse light. A specific configuration of the retarder 183 will be described with reference to FIG. 11.

FIG. 11 is a view schematically showing a configuration of the retarder 183 of the embodiment. As an example, in FIG. 11, the retarder 183 having an 8-stage configuration in which nine beam splitters (for example, half prism) are disposed in series is shown. The retarder 183 includes an input stage 1831 and a delay stage 1832. The input stage 1831 includes an input stage beam splitter 1834A.

The input stage beam splitter 1834A is a beam splitter, into which the pulse light (the retarder incident light 183LI) emitted from the synthesis part 182 first enters, among the above-mentioned nine beam splitters. The input stage beam splitter 1834A divides the entering pulse light, and emits one of them to an input stage mirror 1835 and emits the other to a second stage of beam splitter. The pulse light reflected by the input stage mirror 1835 enters the second stage of beam splitter. Further, in the following description, the optical path that passes through the prism mirror (for example, the input stage mirror 1835) is referred to as a delay optical path, and the optical path that does not pass through the prism mirror is referred to as a non-delay optical path.

The pulse light emitted from the input stage beam splitter 1834A (i.e., passing through the non-delay optical path, non-delayed pulse light) and the pulse light reflected by the input stage mirror 1835 (i.e., passing through the delay optical path, delayed pulse light) enter the second stage of beam splitter. In the second stage of beam splitter, the non-delayed pulse light and the delayed pulse light are synthesized, and are further divided into the delay optical path and the non-delay optical path.

As described above, the beam splitter included in the retarder 183 synthesizes and divides the pulse light by transmitting some of the pulse light and reflecting the other. That is, the retarder 183 (delay optical system) synthesizes and divides the pulse light by transmitting some of the pulse light and reflecting the other.

In addition, the beam splitter (for example, half prism) transmits or reflects the pulse light regardless of the state of the polarization of the pulse light (for example, p-polarized light and s-polarized light). The retarder 183 synthesizes or divides the pulse light using the beam splitter.

The retarder 183 (delay optical system) divides the pulse light synthesized by the synthesis part 182 and delays some of each of the divided pulse lights. That is, the retarder 183 (delay optical system) delays some of the pulse light synthesized by the synthesis part 182.

More specifically, the retarder 183 (delay optical system) changes time characteristics of the pulse light by dividing some of the pulse light to guide it to the delay optical path and synthesizing some of the pulse light guided to the delay optical path to the other of the divided pulse lights. The retarder 183 (delay optical system) synthesizes the pulse light emitted from each of the plurality of light sources, and divides some of the synthesized pulse light to guide them to the delay optical path.

By repeating division and synthesis of the pulse light up to the 8th stage of the retarder 183, one pulse light (see part (B) in FIG. 11) is converted into 256 (that is, 2 raised to the 8th power) group pulse lights (see part (C) in FIG. 11).

That is, the illumination system has a division part configured to divide each of first pulse light and second pulse light into two pulse lights, and a light guide optical system configured to guide one pulse light passing through the division part along a first optical path and to guide the other pulse light passing through the division part along a second optical path longer than the first optical path.

The optical system has a division part configured to divide pulse light into first pulse light and second pulse light, a delay optical system configured to guide the second pulse light to the second optical path longer than the first optical path through which the first pulse light passes, and a synthesis part configured to synthesizes the first pulse light and the second pulse light that passed through the delay optical system.

The illumination system guides the first pulse light and second pulse light synthesized by the synthesis part to the mask and illuminates the mask. Further, as described above, mask may be a photomask or may be a spatial light modulator.

According to the light source unit 18 configured as above, since the temporal characteristics of the plurality of pulse lights are different from each other and the coherence of the pulse light is reduced, occurrence of speckles can be suppressed.

Further, while part (A) in FIG. 11 illustrates the retarder 183 in which the delay optical path is configured by prism mirrors from the first stage to the third stage, and the delay optical path is configured by the optical fiber 1835A having relatively high transmissivity from the fourth stage to the eighth stage, there is no limitation thereto.

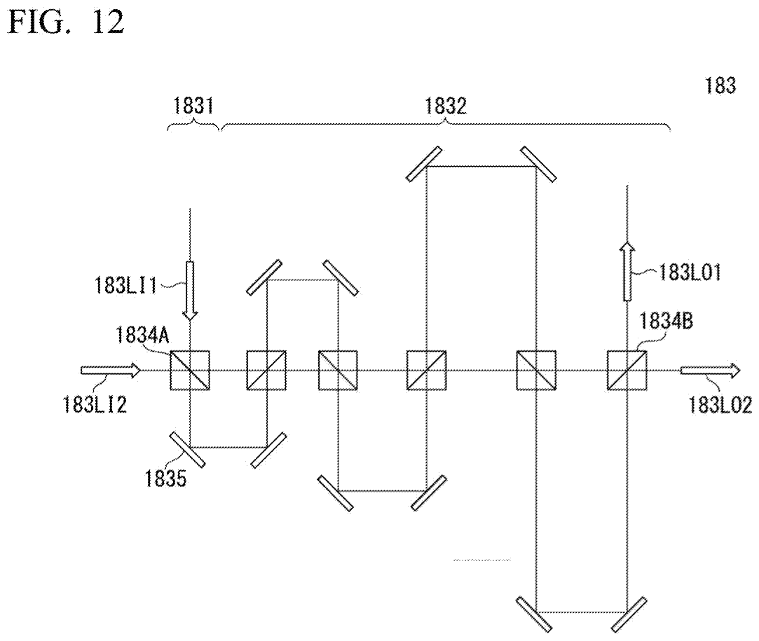

In addition, while the case in which one type of pulse light enters the retarder 183 has been described in part (A) in FIG. 11, there is no limitation thereto. The retarder 183 into which two types of pulse lights enter will be described with reference to FIG. 12.

FIG. 12 is view showing a first variant of a configuration of the retarder 183 of the embodiment. FIG. 12 shows the retarder 183 having a five-stage configuration in which six beam splitters (for example, half prism) are disposed in series as an example.

In the retarder 183 of the variant, two types of pulse lights, i.e., the first retarder incident light 183LI1 and the second retarder incident light 183LI2 enter the input stage beam splitter 1834A.

A final stage beam splitter 1834B emits the first retarder outgoing beam 183LO1 and the second retarder outgoing beam 183LO2.

As described above, in the retarder 183 (delay optical system), the pulse light is emitted by a plurality of routes of, for example, the first retarder outgoing beam 183LO1 and the second retarder outgoing beam 183LO2. The retarder 183 (delay optical system) emits the pulse light to the plurality of distribution parts 184 corresponding to the routes. That is, the retarder 183 of this variant has 2 inputs and 2 outputs.

In other words, the final stage beam splitter 1834B included in the retarder 183 (delay optical system) emits the pulse light through the plurality of routes. The pulse light is guided to the plurality of distribution parts 184 (optical path switching parts) corresponding to the routes, respectively. That is, the delay optical system is configured to emit the pulse light through the plurality of routes, and emits the pulse light to each of the plurality of optical path switching parts corresponding to the routes. Further, the plurality of optical path switching part may be constituted by the plurality of distributors 1842, or may be constituted by different reflecting surfaces of the one distributor 1842.

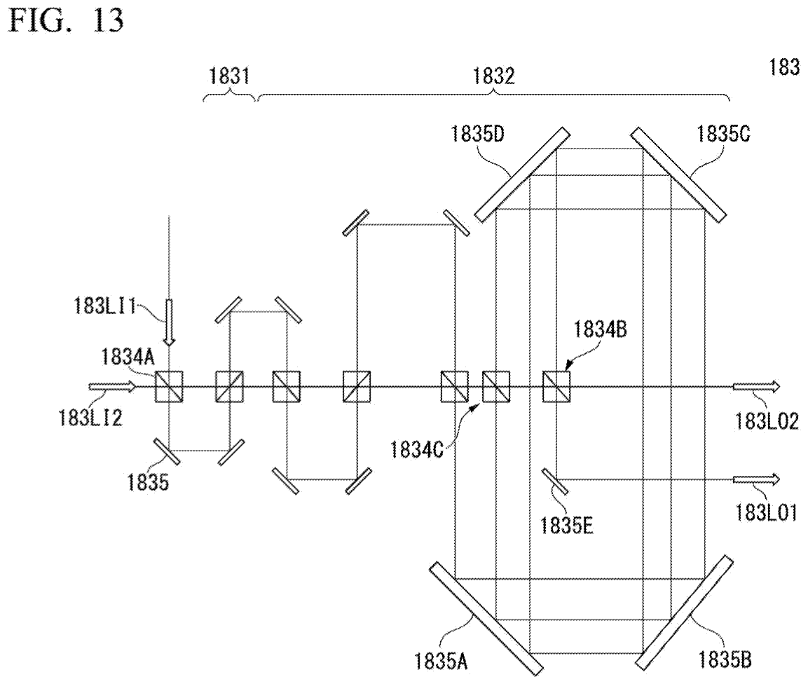

FIG. 13 is a view showing a second variant of a configuration of the retarder 183 of the embodiment. FIG. 13 shows an example of the retarder 183 having a five-sage configuration in which six beam splitters are disposed in series.

The retarder 183 of the variant is configured such that a fifth stage of delay optical path orbits between the mirrors. Specifically, the retarder 183 of the variant includes a first orbiting mirrors 1835A, a second orbiting mirror 1835B, a third orbiting mirror 1835C and a fourth orbiting mirror 1835D. The first orbiting mirrors 1835A to the fourth orbiting mirror 1835D constitute a fifth stage of delay optical path.

As shown in FIG. 13, the retarder 183 has a reflection part (for example, the first orbiting mirrors 1835A) configured to reflect second pulse light, and an optical member through which the reflected second pulse light enters the reflection part again.

The optical member has reflection members (for example, the second orbiting mirror 1835B to the fourth orbiting mirror 1835D). The reflection members (for example, the second orbiting mirror 1835B to the fourth orbiting mirror 1835D) reflect the second pulse light reflected by the reflection part (for example, the first orbiting mirrors 1835A) and cause the second pulse light to enter the reflection part.

That is, the retarder 183 includes an optical member configured to guide the pulse light reflected by the reflection part to the reflection part again. The retarder 183 causes the optical path of the pulse light to circulate (for example, spirally circulate) between the reflection part and the optical member by the reflection part and the optical member.

According to the retarder 183 configured as above, it is possible to suppress an increase in size of the device while further lengthening the optical path length of the delay optical path (i.e., improving speckle reduction performance).

Further, the retarder 183 may include a beam splitter 1834C. The beam splitter 1834C is disposed in an circulating optical path of the pulse light by the first orbiting mirrors 1835A to the fourth orbiting mirror 1835D, and guides some of the orbiting pulse light to the circulating optical path and guides the other to the final stage beam splitter 1834B.

According to the retarder 183 configured as above, since types of the plurality of pulse light having different optical path lengths can be further increased, it is possible to further improve speckle reduction performance while suppressing an increase in size of the device.

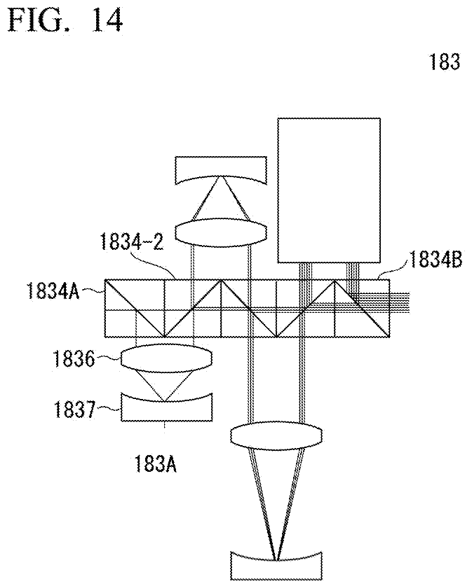

FIG. 14 is a view showing a third variant of a configuration of the retarder 183 of the embodiment. FIG. 14 shows an example of the retarder 183 having a four-stage configuration in which five beam splitters are disposed in series. The retarder 183 of the variant includes a relay lens 1836 and a condensing mirror 1837, and the delay optical path is configured using a Dyson optical system.

More specifically, in a first stage retarder 183A, the pulse light reflected by the input stage beam splitter 1834A is reflected by the condensing mirror 1837 via the relay lens 1836, and enters a second stage beam splitter 1834-2 via the relay lens 1836 again. Even in a second stage retarder 183B to a fifth stage retarder 183E, the delay optical path is configured by repeating condensing and reflection like the first stage retarder 183A.

The input stage beam splitter 1834A functions as a division part that divides light into first pulse light and second pulse light. The relay lens 1836 and the condensing mirror 1837 function as a delay optical system configured to guide the second pulse light to the second optical path longer than the first optical path through which the first pulse light passes. The second stage beam splitter 1834-2 functions as a synthesis part configured to synthesizes the first pulse light and the second pulse light passing through the delay optical system (the relay lens 1836 and the condensing mirror 1837).

As described above, the relay lens 1836 has a rear focus at a position of a surface of the condensing mirror 1837. The rear focus is a focus of the pulse light entering from the first stage retarder 183A, and also a focus of the pulse light emitted to the second stage retarder 183B. That is, the relay lens 1836 guides the pulse light entering from the first stage retarder 183A and the pulse light emitted to the second stage retarder 183B with a common focus. That is, regarding the relay lens 1836, the division surface of the first stage retarder 183A and the division surface of the second stage retarder 183B are conjugate.

Here, the first stage retarder 183A is also referred to as a first division synthesis part. In addition, the second stage retarder 183B is also referred to as a second division synthesis part.

That is, in the retarder 183 (delay optical system), among the plurality of beam splitters (division synthesis parts), a division surface of the first stage retarder 183A (first division synthesis part) configured to divide pulse light into first pulse light and second pulse light and guide the first pulse light to the delay optical path, and a division surface of the second stage retarder 183B (second division synthesis part) configured to synthesize the first pulse light and the second pulse light emitted from the delay optical path are conjugate.

Further, when both the pulse lights can be regarded as almost parallel light with each other, especially when the optical path length difference is short, it is not necessary that the division surface of the first stage retarder 183A (first division synthesis part) and the division surface of the second stage retarder 183B (second division synthesis part) are strictly a conjugate relation. In this case, it may be arranged so as to delay one of the pulse lights by a predetermined distance.

The relay lens 1836 is also referred to as an optical member. The condensing mirror 1837 is also referred to as a reflection part.

That is, the retarder 183 (delay optical system) includes the relay lens 1836 (optical member) and the condensing mirror 1837 (reflection part).

The condensing mirror 1837 (reflection part) reflects the first pulse light emitted from the first stage retarder 183A (first division synthesis part) in a direction of the second stage retarder 183B (second division synthesis part).

The relay lens 1836 (optical member) is disposed on the optical path between the first stage retarder 183A (first division synthesis part) and the second stage retarder 183B (second division synthesis part), causes the first pulse light emitted from the first stage retarder 183A (first division synthesis part) to enter the condensing mirror 1837 (reflection part), and causes the first pulse light reflected by the condensing mirror 1837 (reflection part) to enter the second stage retarder 183B (second division synthesis part).

In other words, the retarder 183 (delay optical system) includes a reflection part (for example, the condensing mirror 1837) and an optical member (for example, the relay lens 1836). The reflection part reflects the second pulse light to guide it to the synthesis part (for example, the second stage beam splitter 1834-2). The optical member is disposed between the division part (for example, the input stage beam splitter 1834A) and the reflection part and between the reflection part and the synthesis part, and causes the second pulse light to enter the reflection part and causes the second pulse light reflected by the reflection part to enter the synthesis part.

The retarder 183 (delay optical system) includes the division part and the synthesis part at a position where the division surface of the division part (for example, the input stage beam splitter 1834A) configured to divide pulse light into first pulse light and second pulse light and the synthesis surface of the synthesis part (for example, the second stage beam splitter 1834-2) configured to synthesize the first pulse light passing through the first optical path and the second pulse light passing through the second optical path are optically conjugated.

As described above, the retarder 183 (delay optical system) is configured to provide at least two stages of the first stage retarder 183A and the second stage retarder 183B. In other words, the retarder 183 (delay optical system) has at least two relay lenses 1836 (optical members) disposed at opposite positions about an axis in a direction of advance of the second pulse light. Among the plurality of optical members, an optical axis of one optical member and an optical axis of the other optical member are separated from each other in the axial direction.

That is, the reflection part has a first reflection part and a second reflection part. The optical member has a first optical member configured to cause the second pulse light divided by the division part to enter the first reflection part, and a second optical member configured to cause the second pulse light reflected by the first reflection part to enter the second reflection part. The first optical member and the second optical member are disposed with their optical axes separated from each other.

As shown in FIG. 14, the reflection part (for example, the condensing mirror 1837) is provided at a position where the focus position of the optical member (for example, the relay lens 1836) becomes the reflecting surface that reflects the second pulse light.

The reflection part (for example, the condensing mirror 1837) reflects the second pulse light so that the second pulse light enters a position different from the position within the optical member through which the second pulse light entering the reflection part passes. That is, the second reflection part reflects the second pulse light and guides the second pulse light to the first reflection part again via the second optical system. The reflection part has a third reflection part. The optical member has a third optical member. The second reflection part reflects the second pulse light, and guides the second pulse light to the third reflection part via the second optical system and the third optical system.

The second stage beam splitter 1834-2 of the retarder 183 functions as both the division part and the synthesis part of the pulse light. The second stage beam splitter 1834-2 (synthesis part) divides the first pulse light into third pulse light and fourth pulse light, and divides the second pulse light into fifth pulse light and sixth pulse light.

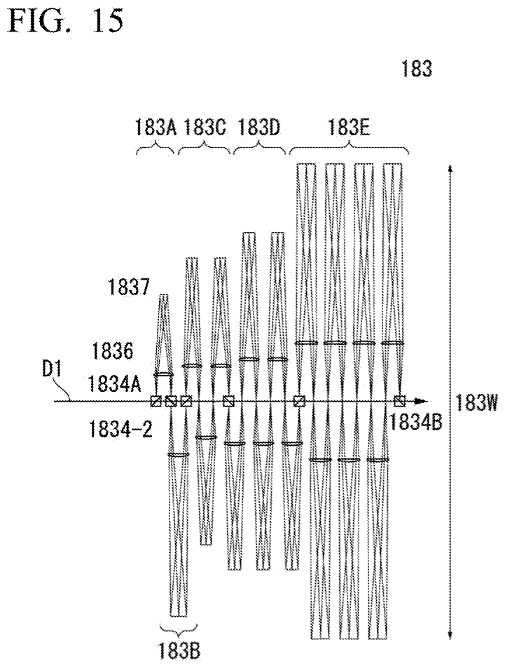

FIG. 15 is a view showing a fourth variant of a configuration of the retarder 183 of the embodiment. FIG. 15 shows an example of the retarder 183 having a five-stage configuration in which six beam splitters are disposed in series. The retarder 183 of the variant includes the first stage retarder 183A to the fifth stage retarder 183E. The first stage retarder 183A to the fifth stage retarder 183E each includes the relay lens 1836 and the condensing mirror 1837, and is configured using a Dyson optical system.

More specifically, in the first stage retarder 183A, the pulse light reflected by the input stage beam splitter 1834A is reflected by the condensing mirror 1837 via the relay lens 1836, and enters the second stage beam splitter 1834-2 via the relay lens 1836 again. Even in the second stage retarder 183B to the fifth stage retarder 183E, the delay optical path is configured by repeating condensing and reflection like the first stage retarder 183A.

An optical path length of the delay optical path increases exponentially with the number of stages of the retarder 183. The retarder 183 of this variant is equipped with the plurality of relay lenses 1836 and the condensing mirror 1837 in stages after the third stage retarder 183C, and has a configuration that folds back the optical path in a direction of a retarder width 183W. According to the retarder 183 configured as above, it is possible to configure a delay optical path with a longer optical path length while suppressing an increase in dimension in a direction of the retarder width 183W.

FIG. 15 shows a case in which each stage of the retarder 183 is configured using a Dyson optical system. That is, the retarder 183 has a lens (corresponding to the relay lens 1836 in FIG. 14) configured to condense the second pulse light passing through a beam splitter 1834 (division part) to a reflection part (corresponding to the condensing mirror 1837 in FIG. 14). The lens guides the second pulse light reflected by the condensing mirror (reflection member) to the next stage of reflecting mirror (reflection member).

Further, each stage of the retarder 183 may not be configured using the Dyson optical system. The retarder 183 may be configured alternately using the delay optical path by the Dyson optical system shown in FIG. 14 or the like and the delay optical path by the prism mirror shown in FIG. 12 or the like for each stage.

In this case, the retarder 183 has a relay lens (lens part) configured to condense the second pulse light passing through the beam splitter (division part) to the condensing mirror. The relay lens guides the second pulse light reflected by the condensing mirror to the next stage of beam splitter. The next stage of beam splitter guides the second pulse light to the prism mirror (reflection part).

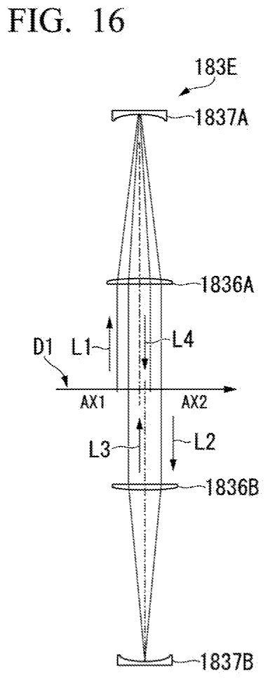

In addition, the rear stage of retarder 183 (for example, the fifth stage retarder 183E), which increases the optical path folding number, can be configured as shown in FIG. 16.

FIG. 16 is a view showing a fifth variant of a configuration of the retarder 183 of the embodiment. FIG. 16 shows an example of a delay optical path by a Dyson optical system employed instead of the fifth stage retarder 183E shown in FIG. 15.

The fifth stage retarder 183E of the variant includes a first relay lens 1836A, a first condensing mirror 1837A, a second relay lens 1836B and a second condensing mirror 1837B.

The first condensing mirror 1837A is disposed at a rear focus position of the first relay lens 1836A. First light L1 entering the first relay lens 1836A is reflected by the first condensing mirror 1837A, and enters the first relay lens 1836A again as second light L2. The second light L2 entering the first relay lens 1836A enters the second relay lens 1836B.

The second condensing mirror 1837B is disposed at a rear focus position of the second relay lens 1836B. The second light L2 entering the second relay lens 1836B is reflected by the second condensing mirror 1837B and enters the second relay lens 1836B again as third light L3. The third light L3 entering the second relay lens 1836B enters the first relay lens 1836A.

The third light L3 entering the first relay lens 1836A is reflected by the first condensing mirror 1837A, and enters the first relay lens 1836A again as fourth light L4.

An optical axis AX2 of the second relay lens 1836B is disposed to be offset in an arrangement direction of the beam splitter 1834 (a direction D1 shown in FIG. 15 and FIG. 16) with respect to an optical axis AX1 of the first relay lens 1836A.

The position where the third light L3 enters the first relay lens 1836A is shifted in the direction D1 by the above-mentioned offset extent with respect to the position where the first light L1 enters the first relay lens 1836A. For this reason, the incidence angle at which the first light L1 enters the first condensing mirror 1837A is different from the incidence angle at which the third light L3 enters the first condensing mirror 1837A. Accordingly, the optical path of the second light L2 reflected by the first condensing mirror 1837A is different from the optical path of the fourth light L4, and the second light L2 and the fourth light L4 can be separated geometrically. For this reason, the fifth stage retarder 183E can extract the fourth light L4 as the retarder outgoing beam 183LO.

In other words, the relay lens 1836 is arranged so that its optical axis is separated from the optical axis of the lens part.

According to the retarder 183 configured as above, it is possible to configure the delay optical path with a longer optical path length while suppressing an increase in the number of parts of the relay lens 1836 and the condensing mirror 1837. Further, in the variant, although the delay optical path configured to repeat condensing and reflection three times has been described, the number of repetitions of condensing and reflection is not limited to this and may be configured to repeat more times.

Here, the direction D1 is also referred to as a direction of advance of the second pulse light. The retarder 183 (delay optical system) includes a set of the relay lens 1836 (optical member) and the condensing mirror 1837 (reflection part) as the delay optical path at opposite positions about an axis in a direction of advance (the direction D1) of the second pulse light. The set of the relay lens 1836 and the condensing mirror 1837 is, for example, a set of “the first relay lens 1836A and the first condensing mirror 1837A,” and a set of “the second relay lens 1836B and the second condensing mirror 1837B.”

The delay optical path constituted by the set of “the first relay lens 1836A and the first condensing mirror 1837A” is also referred to as a first delay optical path, and the delay optical path constituted by the set of “the second relay lens 1836B and the second condensing mirror 1837B” is also referred to as a second delay optical path.

In the delay optical path of the retarder 183 (delay optical system), the optical axis of the optical member (for example, the first relay lens 1836A) that constitutes the first delay optical path and the optical axis of the optical member (for example, the second relay lens 1836B) that constitutes the second delay optical path are offset in the direction D1 (i.e., separated in the direction of the axis).

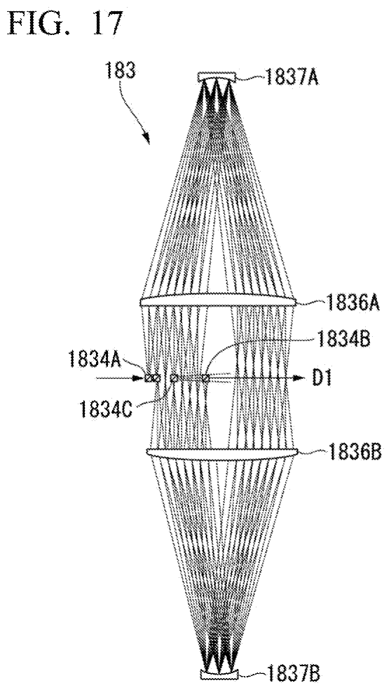

FIG. 17 is a view showing a sixth variant of a configuration of the retarder 183 of the embodiment. FIG. 17 shows an example of the retarder 183 having a three-stage configuration in which four beam splitters are disposed in series. The retarder 183 of the variant is configured using two sets of Dyson optical systems disposed to be opposite with each other in the arrangement direction of the beam splitter 1834 (the direction D1 in FIG. 17) as a target axis.

According to the retarder 183 configured as above, it is possible to configure the delay optical path with a longer optical path length while suppressing an increase in the number of parts of the relay lens 1836 and the condensing mirror 1837. Further, when the incident lights can be regarded as substantially parallel, while the light flux of the concave mirror (for example, the first condensing mirror 1837A or the second condensing mirror) becomes small and may damage lasers with high power, it is also possible to increase the light flux diameter on the concave mirror by condensing the light to a half prism on an incident side using the lens like the example. In this case, it is desirable to make the light fluxes of the non-delay portion and the delay portion have the same diameter, and it is desirable to slightly shift the conjugate relation between the prism mirror positions. FIG. 14 and FIG. 15 are also desirable to be shifted in the same way, but there is no particular problem if the light flux can be regarded as almost parallel like laser.

Further, while the delay optical system performs division and synthesis of the light by the beam splitter (for example, half prism), in consideration of characteristics dispersion or the like of transmissivity and reflectivity of a thin film, a wave plate and a polarization beam splitter may be configured, and transmitted/reflected light may be adjusted by rotating the wave plate.

### [Variant of Distribution Part]

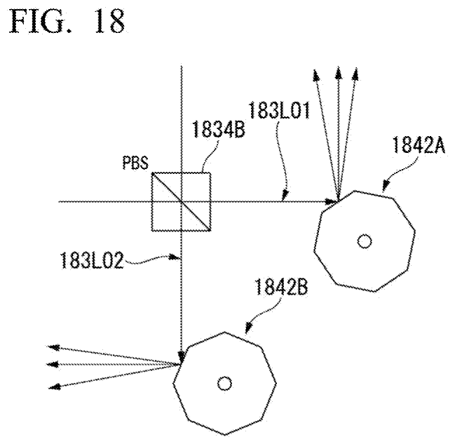

FIG. 18 is a view showing a variant of the distribution part 184. The distribution part 184 of the variant includes two distributors 1842 (a first distributor 1842A and a second distributor 1842B). The first distributor 1842A distributes the first retarder outgoing beam 183LO1 emitted from the final stage beam splitter 1834B. The second distributor 1842B distributes the second retarder outgoing beam 183LO2 emitted from the final stage beam splitter 1834B.

That is, in the configuration of the distribution part 184 shown in FIG. 6, in two different reflecting surfaces of the one distributor 1842, the first retarder outgoing beam 183LO is divided by the first reflecting surface, and the second retarder outgoing beam 183LO2 is divided by the second reflecting surface. Meanwhile, the distribution part 184 of the variant is distinguished from the configuration of the distribution part 184 shown in FIG. 6 in that the first distributor 1842A configured to divide the first retarder outgoing beam 183LO1 and the second distributor 1842B configured to divide the second retarder outgoing beam 183LO2 are provided.

According to the distribution part 184 configured like the variant, it is possible to control rotation speeds of the two distributors 1842. For this reason, according to the distribution part 184 configured like the variant, the rotation speed of the two distributors 1842 can be made different from each other, the coherence of the pulse light can be reduced, and the speckle reduction performance can be further enhanced.

### [Variant of Correspondence Between Distributor and Illumination Module]

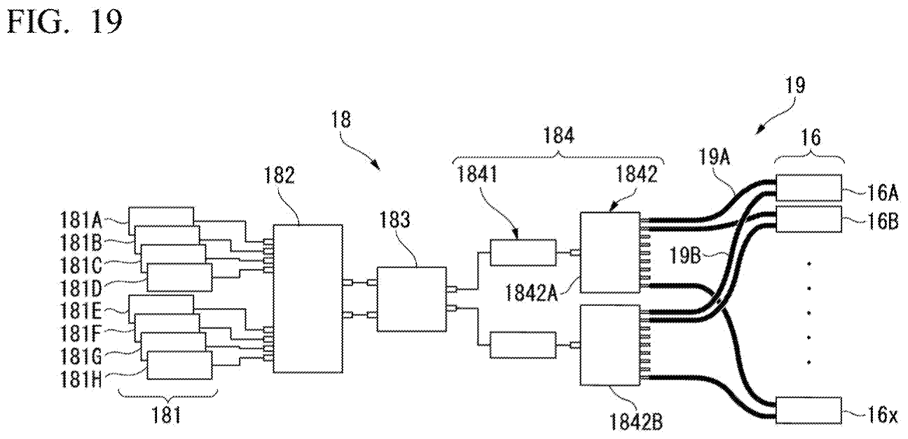

Further, while the case in which the distributor 1842 configured to guide the pulse light to the one illumination module 16 is one has been described in the above-mentioned example, there is no limitation thereto. The distributor 1842 configured to guide the pulse light to the one illumination module 16 may be plural. A variant of correspondence between the distributor 1842 and the illumination module 16 will be described with reference to FIG. 19.

FIG. 19 is a view showing a variant of correspondence between the light source unit 18 and the illumination module 16 of the embodiment.

In the variant, the distributor 1842 includes the first distributor 1842A and the second distributor 1842B. In each of the plurality of illumination modules 16, the light is guided from the first distributor 1842A via the first optical fiber 19A, and the light from the second distributor 1842B is guided via the second optical fiber 19B.

That is, in the variant, the distributor 1842 and the illumination module 16 are provided by n:1 (n is a natural number, and in this example, n=2).

According to the exposure device 1 configured like the variant, the pulse lights distributed to the n (for example, two) distributors 1842 and having different states can be guided to the illumination module 16. For this reason, according to the exposure device 1 configured like the variant, the state of the pulse light emitted from the illumination module 16 can be made more diverse, the coherence of the pulse light can be reduced, and the speckle reduction performance can be further enhanced.

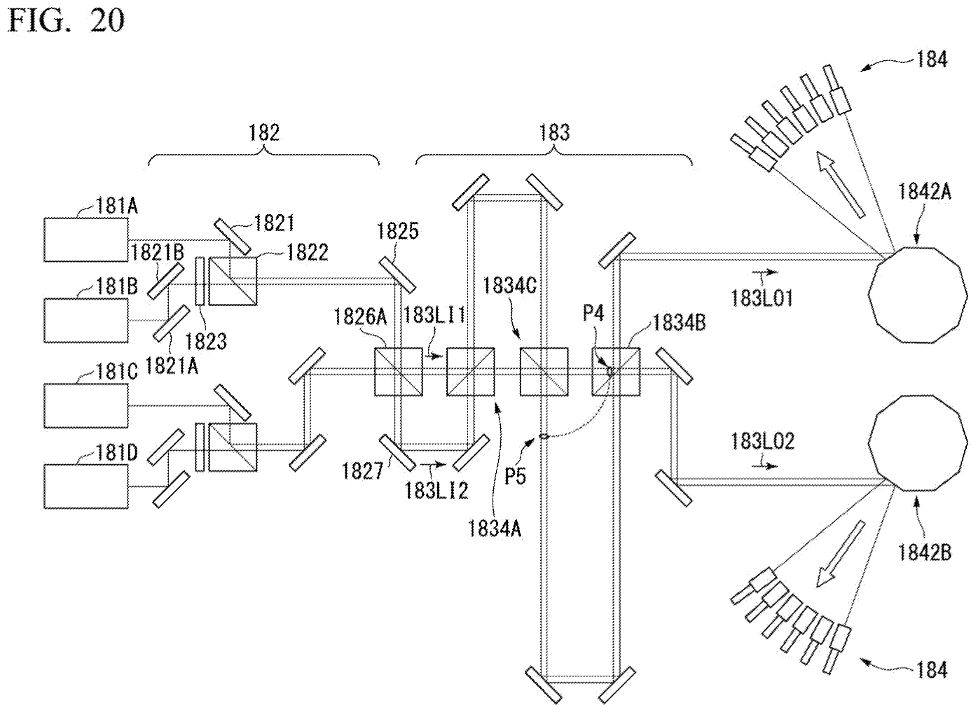

FIG. 20 is a view showing a first variant of the light source unit 18 of the embodiment.

The light source unit 18 of the variant includes four light source parts 181 (the first light source part 181A to the fourth light source part 181D) as an example. In addition, the light source unit 18 of the variant emits the two retarder outgoing beams 183LO (the first retarder outgoing beam 183LO1 and the second retarder outgoing beam 183LO2) to the distributor 1842 from the retarder 183. That is, the light source unit 18 of the variant has a 4-input and 2-output configuration.

The synthesis part 182 includes the prism mirror 1821, the prism mirror 1821A, the prism mirror 1821B, the polarization beam splitter 1822, the wave plate 1823, the prism mirror 1825, a half prism 1826A and the prism mirror 1827 for the first light source part 181A and the second light source part 181B. The prism mirror 1821 guides the pulse light (s-polarized light) emitted from the first light source part 181A to the polarization beam splitter 1822. The prism mirror 1821A and the prism mirror 1821B guide the pulse light (s-polarized light) emitted from the second light source part 181B to the wave plate 1823. The wave plate 1823 changes a polarization state of the pulse light (s-polarized light) emitted from the second light source part 181B and guides the pulse light (p-polarized light) to the polarization beam splitter 1822.

In the synthesis part 182, the third light source part 181C and the fourth light source part 181D also have a configuration corresponding to the configuration of the first light source part 181A and the second light source part 181B. That is, the synthesis part 182 guides the pulse lights from the third light source part 181C and the fourth light source part 181D to the polarization beam splitter 1822.

First light from the first light source part 181A and the second light source part 181B and second light from the third light source part 181C and the fourth light source part 181D enter the half prism 1826A. The half prism 1826A reflects some of the first light and transmits some of the second light, synthesizes these lights, and causes the first retarder incident light 183LI1 to enter an input stage beam splitter 183 included in the retarder 183. In addition, the half prism 1826A transmits the other of the first light and reflects the other of the second light, and synthesizes these lights. The synthesized light is reflected by a prism mirror 1827 and enters the input stage beam splitter 183 as the second retarder incident light 183LI2.

The retarder 183 changes a distribution of a time axis of the pulse light by the delay optical path between the input stage beam splitter 1834A and the final stage beam splitter 1834B. The retarder 183 emits the pulse light with the changed distribution of 20 the time axis to the distribution part 184 as the first retarder outgoing beam 183LO1 and the second retarder outgoing beam 183LO2.

The distribution part 184 of the variant includes the two distributors 1842 (the first distributor 1842A and the second distributor 1842B). The first distributor 1842A distributes the first retarder outgoing beam 183LO1 emitted from the final stage beam splitter 1834B. The second distributor 1842B distributes the second retarder outgoing beam 183LO2 emitted from the final stage beam splitter 1834B.

Further, the synthesis part 182 does not include the prism mirror 1827 as a components, i.e., may include the prism mirror 1821, the prism mirror 1821A, the prism mirror 1821B, the polarization beam splitter 1822, the wave plate 1823, the prism mirror 1825, and the half prism 1826A for the first light source part 181A and the second light source part 181B. When the synthesis part has such a configuration, the retarder 183 includes the half prism 1826A and the prism mirror 1827 in addition to the configuration described above. In that way, the half prism 1826A is a part of the synthesis part 182 and can be referred to as the input stage beam splitter of the retarder 183. The first light entering the input stage beam splitter 1834A shown in FIG. 20 and the second light reflected by the prism mirror and entering the input stage beam splitter 1834A cause a difference in the optical path until the light enters the input stage beam splitter 1834A, and it can be seen that the half prism 1826A and the prism mirror 1827 are part of the retarder 183. This configuration is not limited to the variant and also the same as in another example and another variant, which will be described below.

That is, the light source unit 18 of the variant includes a plurality of light sources, an optical system, and an illumination system. The optical system has a division part, a delay optical system, and a synthesis/division part (for example, the final stage beam splitter 1834B).

The division part divides the pulse light emitted from each of the plurality of light sources into first pulse light and second pulse light. The delay optical system guides the second pulse light to the second optical path longer than the first optical path through which the first pulse light passes. The synthesis part synthesizes the first pulse light and the second pulse light passing through the delay optical system.

The optical system emits the pulse light synthesized by the synthesis parts up to the number of the light sources (for example, four) (for example, two the first retarder outgoing beam 183LO1 and the second retarder outgoing beam 183LO2).

In addition, the optical system may be configured to divide the pulse light synthesized by the synthesis/division part into at least two lights and emit them. In this case, the illumination system illuminates at least two masks by guiding the divided pulse lights to different masks, respectively.

That is, the synthesis/division part synthesizes the pulse lights on the basis of the polarization characteristics of the pulse lights emitted from the plurality of light sources.

According to the light source unit 18 configured as above, since the distributions of the time axes of the plurality of pulse lights are different from each other and the coherence of the pulse light is reduced, occurrence of speckles can be suppressed. In addition, according to the light source unit 18 configured to emit the pulse lights by the number (for example, two) smaller than the number (for example, four) of the light source parts 181, by providing the plurality of light source parts 181, it is possible to emit pulse light with reduced coherence while increasing the power of the pulse light.

Further, the light source unit 18 may have the division part and the synthesis part provided at a position where the predetermined position on the delay optical path divided by the division part and the synthesis surface on which the pulse lights are synthesized in the synthesis part are substantially optically conjugated. More specifically, the light source unit 18 may have the division part and the synthesis part provided at a position where a position where the pulse light emitted from the beam splitter 1834C to the non-delay-side optical path enters the next stage of beam splitter (for example, the final stage beam splitter 1834B) to be synthesized and divided and a predetermined position of (for example, a position P5 shown in FIG. 20) the pulse light emitted from the beam splitter 1834C to the delay-side optical path are substantially optically conjugated. In addition, the light source unit 18 may include a relay lens (not shown) on the delay optical path where the predetermined position (for example, the position P5 shown in FIG. 20) on the delay optical path divided by the division part and the synthesis surface (for example, a position P4 shown in FIG. 20) on which the pulse light is synthesized in the synthesis part are substantially optically conjugated. This is because the retarder makes the delay optical path longer, for example, a distance between the division surface of the beam splitter 1834C and the division surface of the final stage beam splitter 1834B becomes longer, and the light is easily relayed by providing a conjugate point between the division surfaces once.

According to the light source unit 18 configured as above, the pulse light divided by the division part and guided to the delay optical path and the pulse light guided to the non-delay optical path are easily synthesized on the synthesis surface, and the speckles can be further reduced.

In addition, in the light source unit 18, the optical path lengths of the optical paths that cause the pulse light to enter the input stage beam splitter 1834A from the plurality of light source parts 181 may be substantially equal to each other.

According to the light source unit 18 configured as above, the conditions of the time axis of the pulse light emitted from each of the plurality of light source parts 181 can be matched, and the adjustment of the pulse light for speckle reduction can be facilitated.

In addition, in the light source unit 18, the optical path lengths of the optical paths that cause the pulse light to enter the input stage beam splitter 1834A from the plurality of light source parts 181 may be different from each other.

According to the light source unit 18 configured as above, even when the pulse light is emitted simultaneously from the plurality of light source parts 181, dispersion can be given to the time axis conditions among the emitted pulse lights, making it easy to adjust the pulse lights for speckle reduction.

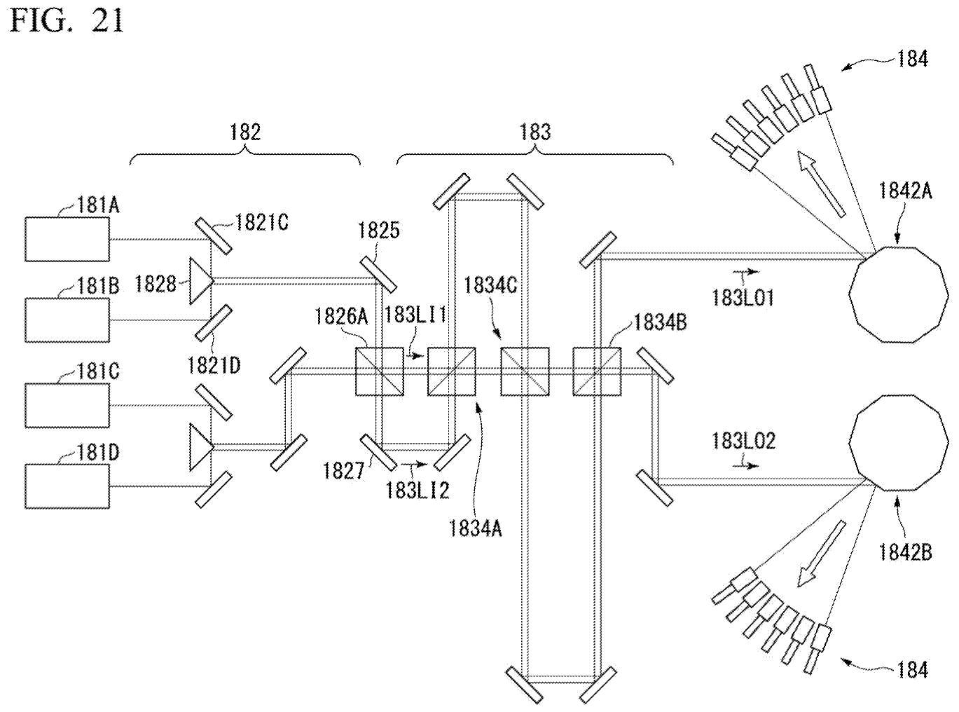

FIG. 21 is a view showing a second variant of the light source unit 18 of the embodiment.

The light source unit 18 of the variant includes the four light source parts 181 (the first light source part 181A to the fourth light source part 181D) as an example. In addition, the light source unit 18 of the variant emits the two retarder outgoing beams 183LO (the first retarder outgoing beam 183LO1 and the second retarder outgoing beam 183LO2) from the retarder 183 to the distributor 1842. That is, the light source unit 18 of the variant has a four-input and two-output configuration.

The light source unit 18 of the variant includes a triangular prism mirror 1828, instead of the polarization beam splitter 1822 and the wave plate 1823 of the above-mentioned first variant.

The synthesis part 182 includes the prism mirror 1821C, the prism mirror 1821D, the triangular prism mirror 1828, the prism mirror 1825, the half prism 1826A and the prism mirror 1827 for the first light source part 181A and the second light source part 181B.

The prism mirror 1821C guides the pulse light (s-polarized light) emitted from the first light source part 181A to the triangular prism mirror 1828. The prism mirror 1821D guides the pulse light (s-polarized light) emitted from the second light source part 181B to the triangular prism mirror 1828.

The triangular prism mirror 1828 guides the pulse light emitted from the first light source part 181A and the pulse light emitted from the second light source part 181B to the half prism 1826A via the prism mirror 1825.

In the synthesis part 182, the third light source part 181C and the fourth light source part 181D also have a configuration corresponding to the configuration of the first light source part 181A and the second light source part 181B. That is, the synthesis part 182 guides the pulse lights from the third light source part 181C and the fourth light source part 181D to the half prism 1826A via the triangular prism mirror.

The first light from the first light source part 181A and the second light source part 181B and the second light from the third light source part 181C and the fourth light source part 181D enter the half prism 1826A. The half prism 1826A reflects some of the first light, transmits some of the second light, synthesizes these lights, and causes the first retarder incident light 183LI1 to enter the input stage beam splitter 183 included in the retarder 183. In addition, the half prism 1826A transmits the other of the first light, reflects the other of the second light, and synthesizes these lights. The synthesized light is reflected by the prism mirror 1827 and enters the input stage beam splitter 183 as the second retarder incident light 183LI2.

That is, in the variant, the triangular prism mirror 1828 visually synthesizes the pulse lights from the plurality of light source parts 181 and causes it to enter the half prism 1826A. Here, the visual synthesis is to synthesize the pulse light by making the optical paths of the pulse lights close to each other, in other words, bringing the optical axes close to each other. In addition, it can be said that the visual synthesis is to make the optical paths of the pulse lights close to each other so that it can be relayed by a single optical system.

That is, the light source unit 18 of the variant is provided with a light guide part including the triangular prism mirror 1828. The light guide part makes the optical paths of the pulse lights that are emitted from the plurality of light sources (for example, the first light source part 181A and the second light source part 181B) close to each other within a range into which the light can enter the division part (for example, the half prism 1826A), and guides the pulse light to the division part.

According to the light source unit 18 configured as above, since the distributions of the time axes of the plurality of pulse lights are different from each other and the coherence of the pulse light is reduced, the occurrence of speckles can be suppressed. In addition, according to the light source unit 18 configured to emit the pulse lights by the number (for example, two) smaller than the number (for example, four) of the light source parts 181, it is possible to emit the pulse light with the reduced coherence while increasing the power of the pulse light by providing the plurality of light source parts 181.

In addition, according to the light source unit 18 configured as above, in consideration of the laser resistance and life of the optical parts, the triangular prism mirror 1828 can actively shift the optical paths of the pulse lights. By actively shifting the optical paths of the pulse lights (for example, increasing the distance between the optical paths of the pulse lights), for example, in the optical parts such as the half prism 1826A and the like, a condensing level of the power of the plurality of pulse lights can be decreased, and lifespan of the optical parts can be increased.

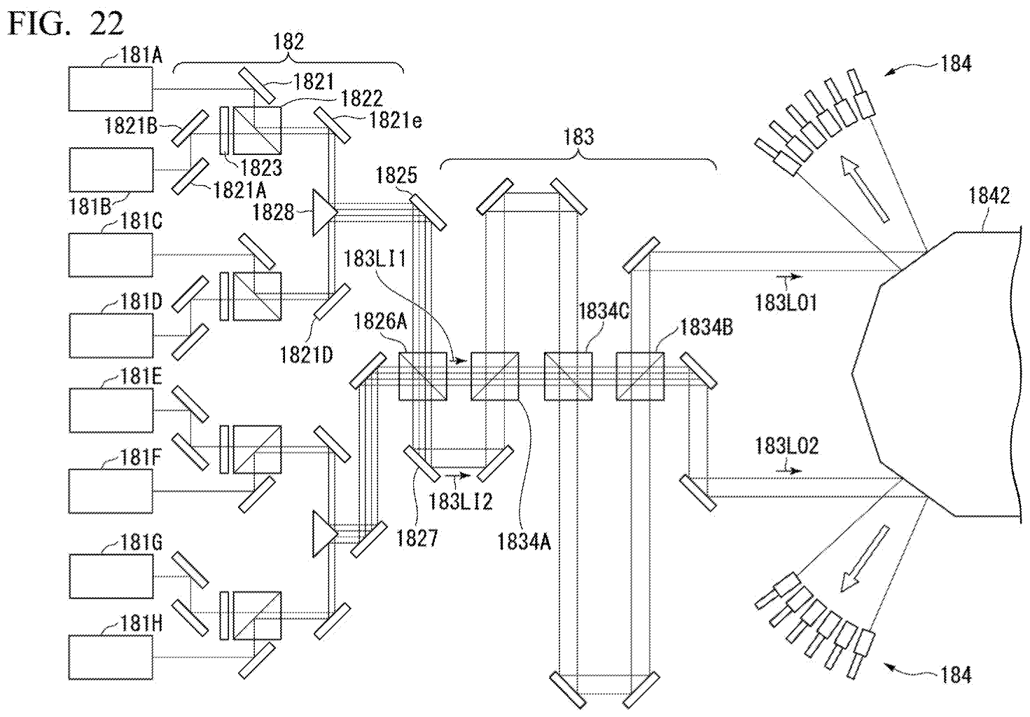

FIG. 22 is a view showing a third variant of the light source unit 18 of the embodiment.

The light source unit 18 of the variant includes the eighth light source parts 181 (the first light source part 181A to the eighth light source part 181H) as an example. In addition, the light source unit 18 of the variant emits the two retarder outgoing beams 183LO (the first retarder outgoing beam 183LO1 and the second retarder outgoing beam 183LO2) from the retarder 183 to the distributor 1842. That is, the light source unit 18 of the variant has an 8-input and 2-output configuration.

The light source unit 18 of the variant synthesizes the pulse lights by combining the synthesis based on the polarization characteristics of the pulse lights using the polarization beam splitter 1822 in the above-mentioned first variant and the visual synthesis using the triangular prism mirror 1828 in the second variant.

According to the light source unit 18 configured as above, since the pulse lights from the larger number of (for example, eight) light source parts 181 can be synthesized, the coherence of the pulse light can be further reduced and occurrence of speckles can be suppressed.

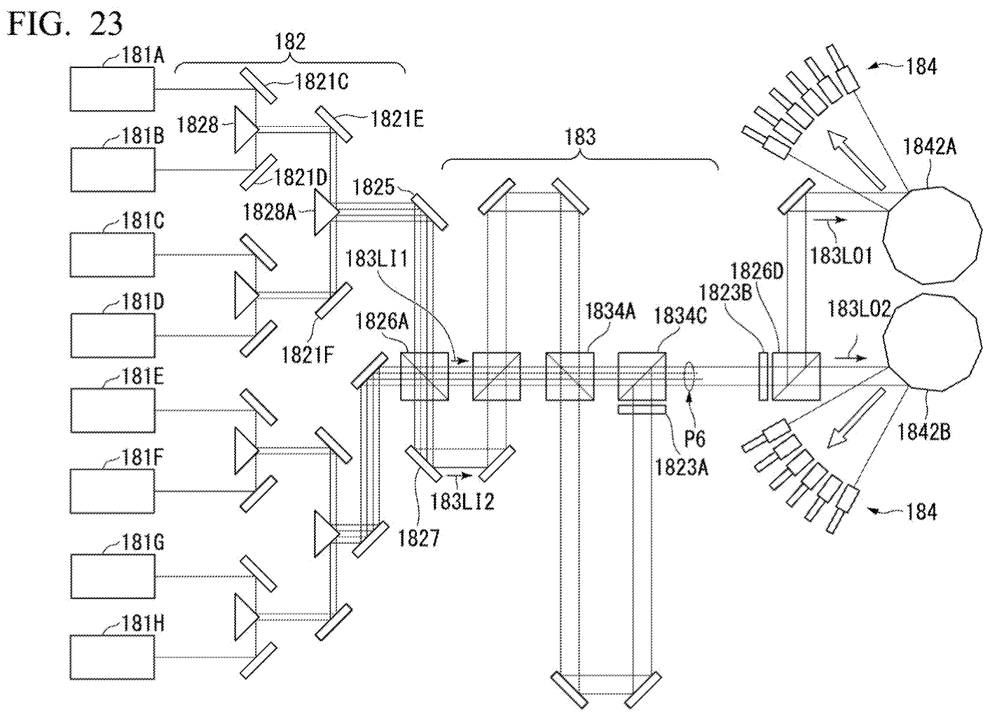

FIG. 23 is a view showing a fourth variant of the light source unit 18 of the embodiment.

The light source unit 18 of the variant includes the eighth light source parts 181 (the first light source part 181A to the eighth light source part 181H) as an example. In addition, the light source unit 18 of the variant emits the two retarder outgoing beams 183LO (the first retarder outgoing beam 183LO1 and the second retarder outgoing beam 183LO2) from the retarder 183 to the distributor 1842. That is, the light source unit 18 of the variant has an 8-input and 2-output configuration.

The light source unit 18 of the variant synthesizes eighth pulse lights by visual synthesis using the triangular prism mirror 1828 in the above-mentioned second variant.

The retarder 183 of the variant includes the polarization beam splitter 1826C, the polarization beam splitter 1826D, the wave plate 1823A and the wave plate 1823B, instead of a half prism 1826B of the retarder 183 in the above-mentioned second variant.

The wave plate 1823A changes a polarization state of the pulse light entering from the delay optical path to the polarization beam splitter 1826C. In the polarization beam splitter 1826C, the pulse light entering from the non-delay optical path and the pulse light entering from the wave plate 1823A are synthesized, and the synthesized pulse light is emitted to a position P6 shown in FIG. 23.

The wave plate 1823B changes a polarization state of the pulse light entering from the position P6 (i.e., the synthesized pulse light in the polarization beam splitter 1826C).

The polarization beam splitter 1826D divides the pulse light into the first retarder outgoing beam 183LO1 and the second retarder outgoing beam 183LO2 and emits them on the basis of the polarization state of the pulse light entering from the wave plate 1823B.

Further, in the variant, the pulse light at the position P6 (i.e., the pulse light synthesized in the polarization beam splitter 1826C) may be emitted to the distributor 1842 without providing the wave plate 1823B and the polarization beam splitter 1826D. In the case of this configuration, the light source unit 18 has an 8-input and 1-output configuration.

Further, in the above-mentioned embodiment and the variant thereof, although the triangular prism mirror 1828 has been described as realizing visual synthesis, there is no limitation thereto. For example, the visual synthesis may be realized by the above-mentioned polarization beam splitter. In addition, for example, in the polarization beam splitter or the non-polarization type half prism, visual synthesis may be achieved by shifting the incident position of the pulse light to the division surface that divides the pulse light.

Further, the method of reducing the coherence of the pulse light described above may lead to reduction in the contrast of the integrated image during scanning exposure. The reduction in the contrast of the integrated image during the scanning exposure occurs as an image flow due to the progress of the image during the exposure. It is preferable that the flow amount of the image is kept within about ⅓ to ¼ of the resolution.

For example, an allowable delay time Δt of the pulse light is Δt=2/4/1000=0.5 μsec, assuming that resolution is 2 μm and a scanning speed is 1000 mm/s when the flow amount of the image that causes the contrast reduction of the integrated image during scanning exposure is kept to ¼ of the resolution. Here, if the pulse emission width is 4 ns, it is possible to divide up to 125 (≈128) pulses.

In addition, for example, the allowable delay time Δt of the pulse light is Δt=2/3/1000=0.67 μsec, assuming that resolution is 2 μm and a scanning speed is 1000 mm/s when the contrast reduction of the integrated image during scanning exposure is kept to ⅓ of the resolution.

In this way, the pulse width of the group pulse light synthesized from the pulse lights delayed by the delay optical system of the retarder 183 is preferably set so that the product of the image flow due to the scanning speed of the exposure device 1 is ⅓ or less of the resolution.

For example, in the exposure device 1, when the stage 14 is relatively moved with respect to the projection module 17 (projection optical system) at a predetermined speed, provided that a time difference between the first time point that is a light emission timing of the first pulse light and the second time point that is a light emission timing of the second pulse light is δ, the predetermined speed is V and the resolution is R, R/3<V·δ is satisfied.

In addition, the first light source part 181A and the second light source part 181B emit the first pulse light and the second pulse light that satisfy λ>Δ×(NA\hat{ }2). Here, λ indicates a wavelength difference between the first pulse light and the second pulse light, Δ indicates chromatic aberration of the projection optical system generated by the wavelength difference between the first pulse light and the second pulse light, and NA indicates a numerical aperture of the projection optical system. \hat{ }₂ means square.

Further, the disclosures of all published US patent applications and US patents relating to exposure devices, and the like, cited in the above embodiment are hereby incorporated by reference.

As described above, the illumination device and the exposure device of the present invention are suitable for irradiating and exposing an object with illumination light in a lithography process. In addition, the method for manufacturing the flat panel display of the present invention is suitable for production of the flat panel display.

What is claimed is:

1. An illumination optical system comprising:
a plurality of light sources each configured to emit pulse light;
an optical system including:
(i) a division part configured to divide the pulse light emitted from each of the plurality of light sources into first pulse light and second pulse light;
(ii) a delay optical system configured to guide the second pulse light to a second optical path longer than a first optical path through which the first pulse light passes; and
(iii) a synthesis/division part configured to synthesize the second pulse light that has passed through the delay optical system and the first pulse light and to divide and emit the synthesized pulse light; and
an illumination system configured to guide the pulse lights emitted from the optical system so as to illuminate a mask on which a predetermined pattern is formed.

2. An illumination optical system comprising:
a plurality of light sources each configured to emit pulse light;
an optical system including a synthesis/division part configured to synthesize the pulse light emitted from each of the plurality of light sources, and to divide and emit the synthesized pulse light; and
an illumination system configured to guide each of the pulse lights emitted from the optical system so as to illuminate a mask on which a predetermined pattern is formed.

3. The illumination optical system according to claim 1,
wherein the synthesis/division part is configured to divide the synthesized pulse light into at least two pulse lights, and
wherein the illumination system is configured to guide the divided pulse lights to different masks.

4. The illumination optical system according to claim 1, wherein the synthesis/division part is configured to divide the synthesized pulse light and to emit the pulse lights in a number less than or equal to a number of the light sources.

5. The illumination optical system according to claim 1, wherein the optical system includes a light guide part configured to make optical paths of the pulse lights emitted from the plurality of light sources close to each other within a range in which the pulse lights enter the optical system, and to guide the pulse lights to the division part.

6. The illumination optical system according to claim 5, wherein, among the light guide members included in the illumination system, the light guide part is configured to make the pulse lights close to each other within a range in which the plurality of pulse lights enter a same light guide member.

7. The illumination optical system according to claim 6, wherein the light guide part is configured to make the pulse lights close to each other and to make an interval between emission positions of the plurality of pulse lights smaller than a diameter of the light guide member.

8. The illumination optical system according to claim 5, wherein the light guide part includes a reflection member configured to reflect entering pulse light and change a direction of an optical path so as to make optical paths of the pulse lights close to each other.

9. The illumination optical system according to claim 5, wherein the light guide part includes a polarization member configured to make optical paths of the pulse lights close to each other on the basis of polarization characteristics of the pulse lights emitted from the plurality of light sources.

10. The illumination optical system according to claim 1,
wherein the illumination system includes an optical path switching part configured to switch optical paths of the pulse lights emitted from the optical system and to sequentially guide the pulse lights to the masks provided in plural, and
wherein the light source and the optical path switching part are provided at a position where an emission position of the pulse light of the light source and an incidence position where the pulse light enters the optical path switching part are substantially optically conjugated.

11. The illumination optical system according to claim 10,
wherein the illumination system includes a light guide part configured to guide the pulse light emitted from the optical path switching part to the mask, and
wherein the optical path switching part and the light guide part are provided at a position where an emission position at which the pulse light is emitted from the optical path switching part and the incidence position of the pulse light of the light guide part are substantially optically conjugated.

12. The illumination optical system according to claim 11, wherein the illumination system includes a relay lens that is disposed between the optical path switching part and the light guide part and that is configured to make an emission position where the pulse light is emitted from the optical path switching part and an incidence position of the pulse light of the light guide part substantially optically conjugated.

13. The illumination optical system according to claim 1, wherein, in a case the optical system includes a plurality of stages of synthesis/division parts, front stage and rear stage synthesis/division parts are provided at positions where a predetermined position on the delay optical path divided by the front stage synthesis/division part and a synthesis surface on which pulse lights are synthesized at the rear stage synthesis/division part are substantially optically conjugated.

14. The illumination optical system according to claim 1, wherein, in a case the optical system includes a plurality stages of synthesis/division parts, a relay lens, which makes a predetermined position on the delay optical path divided by a front stage synthesis/division part and a synthesis surface on which pulse lights are synthesized at a rear stage synthesis/division part substantially optically conjugated, is provided on the delay optical path.

15. The illumination optical system according to claim 1, wherein optical path lengths of each optical paths of the pulse light entering the optical system from the plurality of light sources are substantially equal to each other.

16. The illumination optical system according to claim 1, wherein optical path lengths of each optical paths of the pulse lights entering the optical system from the plurality of light sources are different from each other.

17. An exposure device comprising:
the illumination optical system according to claim 1;
a projection optical system configured to divisionally expose an exposure target by irradiating an exposure target with light emitted from the mask illuminated by the pulse light; and
a stage on which the exposure target is placeable.

18. The exposure device according to claim 17,
wherein the light source is a laser light source whose emitted light wavelength is 360 nm or less, and
wherein the projection optical system is constituted by one or two types of glass material.

19. The exposure device according to claim 18, wherein the glass material is quartz or fluorite.

20. The exposure device according to claim 17, wherein a pulse width of group pulse light in which the pulse lights delayed by a delay optical system of the optical system are synthesized is set such that a product of flows of images according to a scanning speed of the exposure device is ⅓ or less of a resolution.

21. The exposure device according to claim 17, wherein the exposure target includes at least one side length or a diagonal length of 500 mm or more, and is a substrate for a flat panel display.

22. The exposure device according to claim 17, wherein the mask is a spatial light modulator.

23. A method for manufacturing a flat panel display comprising:
exposing an exposure target using the exposure device according to claim 17; and
developing the exposed exposure target.

24. An illumination optical system comprising:
a first light source configured to emit first pulse light at a first time point;
a second light source configured to emit second pulse light at a second time point different from the first time point; and
an illumination system configured to guide each of the first pulse light and the second pulse light to a spatial light modulator in which a plurality of elements are individually controlled at a predetermined time interval,
wherein the second light source is configured to emit the second pulse light at the second time point in which a time interval from the first time point is shorter than the predetermined time interval.

25. The illumination optical system according to claim 24,
wherein the first light source is configured to continuously emit the first pulse light at a predetermined period, and
wherein the second light source is configured to continuously emit the second pulse light at the predetermined period.

26. The illumination optical system according to claim 25, wherein the second light source is configured to emit the second pulse light during an interval of the continuous first pulse lights emitted from the first light source.

27. The illumination optical system according to claim 25, wherein the first and second light sources are configured to continuously emit the first pulse light and the second pulse light, respectively, at the predetermined period which is a time interval shorter than the predetermined time interval at which the elements are controlled.

28. The illumination optical system according to claim 24,
wherein the first light source includes a first seed light source, and
wherein the second light source includes a second seed light source different from the first seed light source, and is configured to control the second seed light source so as to emit the second pulse light at the second time point.

29. The illumination optical system according to claim 24, wherein the first light source is configured to emit the first pulse light with a wavelength different from the second pulse light emitted from the second light source.

30. The illumination optical system according to claim 24, wherein the illumination system includes a phase changing part configured to temporally change a phase state of at least one of the first pulse light and the second pulse light.

31. The illumination optical system according to claim 30,
wherein the illumination system includes an optical transmission part configured to guide the first pulse light and the second pulse light to the spatial light modulator, and
wherein the phase changing part adjusts at least one of incidence angle or incidence position of the first and second pulse lights entering the optical transmission part.

32. The illumination optical system according to claim 31, wherein the illumination system includes an optical path switching machine configured to switch optical paths of the first and second pulse lights sequentially oscillated from the first and second light sources and to sequentially guide them to the optical transmission parts that are provided in plural.

33. The illumination optical system according to claim 32,
wherein the optical path switching machine includes a reflecting surface configured to reflect the first and second pulse lights, and is configured to change an incidence angle of the reflecting surface with respect to the first and second pulse lights to switch the optical paths, and
wherein the phase changing part is configured to control the optical path switching machine to adjust incidence angle of the first and second pulse lights entering the optical transmission part.

34. The illumination optical system according to claim 31, wherein a plurality of optical transmission parts are configured to guide the first pulse light and the second pulse light to one spatial light modulator.

35. The illumination optical system according to claim 31,
wherein a first optical transmission part among a plurality of optical transmission parts is configured to guide the first pulse light and the second pulse light to a first spatial light modulator among a plurality of provided spatial light modulators, and
wherein a second optical transmission part among the plurality of optical transmission parts is configured to guide the first pulse light and the second pulse light to a second spatial light modulator among the plurality of provided spatial light modulators.

36. The illumination optical system according to claim 30, wherein the phase changing part includes a diffusion plate configured to diffuse light entering the spatial light modulator.

37. The illumination optical system according to claim 24, wherein the illumination system includes a delay optical system including (i) a division member configured to divide each of the first pulse light and the second pulse light into two pulse lights and (ii) a light guide optical system configured to guide one pulse light passing through the division member along a first optical path and to guide the other pulse light passing through the division member along a second optical path longer than the first optical path.

38. The illumination optical system according to claim 37, wherein at least one of the first optical path and the second optical path is variable.

39. An exposure device comprising:
the illumination optical system according to claim 24; and
a projection optical system configured to divisionally expose a substrate by irradiating the substrate with light emitted from each of the plurality of spatial light modulators illuminated by the first and second pulse lights.

40. The exposure device according to claim 39, wherein exposure is performed by changing a brightness state of a pupil according to substantial illumination light at an arbitrary exposure position.

41. An exposure device comprising:
the illumination optical system according to claim 24;
a projection optical system configured to project an image of the spatial light modulator illuminated by the illumination optical system on a substrate; and
a substrate stage configured to support the substrate and relatively move with respect to the projection optical system at a predetermined speed when the image of the spatial light modulator is exposed to the substrate,
wherein, provided that a time difference between the first time point and the second time point is δ, the predetermined speed is V, and resolution of the image is R,
R/3<V·δ is satisfied.

42. An exposure device comprising:
the illumination optical system according to claim 29; and
a projection optical system configured to project an image of the spatial light modulator illuminated by the illumination optical system on a substrate,
wherein the first and second light sources are configured to emit the first pulse light and the second pulse light that satisfy
λ>Δ×(NA\hat{ }2)
provided that a wavelength difference between the first pulse light and the second pulse light is λ, chromatic aberration of the projection optical system occurring due to the wavelength difference between the first pulse light and the second pulse light is Δ, and a numerical aperture of the projection optical system is NA.

43. The exposure device according to claim 39,
wherein the first light source and the second light source are laser light sources whose emitting light wavelength is 360 nm or less, and
wherein the projection optical system is constituted by one or two types of glass material.

44. The exposure device according to claim 43, wherein the glass material is quartz or fluorite.

45. A device manufacturing method comprising:
exposing the substrate using the exposure device according to claim 39; and
developing the exposed substrate.

46. A method for manufacturing a flat panel display, comprising:
exposing a substrate for a flat panel display using the exposure device according to claim 39; and
developing the exposed substrate.

47. An illumination method performed in an illumination optical system configured to illuminate a spatial light modulator in which a plurality of elements are individually controlled at a predetermined time interval, the method comprising:
emitting first pulse light from a first light source at a first time point;
emitting second pulse light from a second light source at a second time point which is different from the first time point and in which a time interval from the first time point is shorter than the predetermined time interval; and
guiding each of the first and second pulse lights to the spatial light modulator and illuminating the spatial light modulator using the illumination optical system.

48. A device manufacturing method comprising:
exposing an image of the spatial light modulator illuminated by the illumination method according to claim 47; and
developing the exposed substrate.

49. A method for manufacturing a flat panel display, comprising:
exposing an image of the spatial light modulator illuminated by the illumination method according to claim 47 on a substrate; and
developing the exposed substrate.

50. An illumination optical system comprising:
a light source configured to emit pulse light;
an optical system including:
(i) a division part configured to divide the pulse light into first pulse light and second pulse light;
(ii) a delay optical system configured to guide the second pulse light to a second optical path longer than a first optical path through which the first pulse light passes; and
(iii) a synthesis part configured to synthesize the second pulse light which has passed through the delay optical system and the first pulse light; and
an illumination system configured to guide the first and second pulse lights synthesized by the synthesis part to a mask on which a predetermined pattern is formed,
wherein the delay optical system includes a reflection part configured to reflect the second pulse light, and an optical member configured to cause the reflected second pulse light to enter the reflection part again.

51. The illumination optical system according to claim 50, wherein the optical member includes a reflection member configured to reflect the second pulse light reflected by the reflection part and to cause the second pulse light to enter the reflection part.

52. The illumination optical system according to claim 51,
wherein the delay optical system includes a lens configured to condense the second pulse light which has passed through the division part to the reflection part, and
wherein the lens is configured to guide the second pulse light reflected by the reflection part to the reflection member.

53. The illumination optical system according to claim 52,
wherein the optical member includes a lens part configured to condense the second pulse light reflected by the reflection part to the reflection member, and
wherein the lens part is configured to guide the second pulse light reflected by the reflection member to the reflection part.

54. The illumination optical system according to claim 53, wherein the lens is disposed such that an optical axis thereof is separated from an optical axis of the lens part.

55. The illumination optical system according to claim 51,
wherein the optical member includes a lens part configured to condense the second pulse light reflected by the reflection part to the reflection member, and
wherein the lens part is configured to guide the second pulse light reflected by the reflection member to the reflection part.

56. An illumination optical system comprising:
a light source configured to emit pulse light;
an optical system including:
(i) a division part configured to divide the pulse light into first pulse light and second pulse light;
(ii) a delay optical system configured to guide the second pulse light to a second optical path longer than a first optical path through which the first pulse light passes; and
(iii) a synthesis part configured to synthesize the second pulse light which has passed through the delay optical system and the first pulse light; and
an illumination system configured to guide the first and second pulse lights synthesized by the synthesis part to a mask on which a predetermined pattern is formed,
wherein the delay optical system includes a reflection part configured to reflect the second pulse light and to guide the reflected second pulse light to the synthesis part, and an optical member that is disposed between the division part and the reflection part and between the reflection part and the synthesis part, that is configured to cause the second pulse light to enter the reflection part, and that is configured to cause the second pulse light reflected by the reflection part to enter the synthesis part, and
wherein the delay optical system includes the division part and the synthesis part that are provided at positions where a division surface of the division part configured to divide the pulse light into the first pulse light and the second pulse light and a synthesis surface of the synthesis part configured to synthesize the first pulse light which has passed through the first optical path and the second pulse light which has passed through the second optical path are substantially optically conjugated.

57. The illumination optical system according to claim 56,
wherein the reflection part includes a first reflection part and a second reflection part,
wherein the optical member includes a first optical member configured to cause the second pulse light divided by the division part to enter the first reflection part and a second optical member configured to cause the second pulse light reflected by the first reflection part to enter the second reflection part, and
wherein the first and second optical members are disposed with their optical axes separated from each other.

58. The illumination optical system according to claim 57, wherein the second reflection part is configured to reflect the second pulse light and to guide the second pulse light to the first reflection part again via the second optical member.

59. The illumination optical system according to claim 57,
wherein the reflection part includes a third reflection part,
wherein the optical member includes a third optical member, and
wherein the second reflection part is configured to reflect the second pulse light and to guide the second pulse light to the third reflection part via the second optical member and the third optical member.

60. The illumination optical system according to claim 56, wherein the reflection part is configured to reflect the second pulse light at a focus position of the optical member.

61. The illumination optical system according to claim 56, wherein the reflection part is configured to reflect the second pulse light so that the second pulse light enters the optical member at a position different from a position in the optical member through which the second pulse light that enters the reflection part passes.

62. The illumination optical system according to claim 56, wherein the synthesis part is configured to divide the first pulse light into third pulse light and fourth pulse light, to divide the second pulse light into fifth pulse light and sixth pulse light, to synthesize the third pulse light and the fifth pulse light, and to synthesize the fourth pulse light and the sixth pulse light.

63. The illumination optical system according to claim 56, wherein the illumination system includes an optical path switching part configured to switch an optical path of the synthesized pulse light and to sequentially guide the pulse lights to the masks provided in plural.

64. An illumination optical system comprising:
a light source configured to emit pulse light;
an optical system including:
(i) a division part configured to divide the pulse light into first pulse light and second pulse light,
(ii) a delay optical system configured to guide the second pulse light to pass through a second optical path longer than a first optical path through which the first pulse light passes, and
(iii) a synthesis part configured to synthesize the first and second pulse lights passing through the delay optical system; and
an illumination system configured to guide the pulse light synthesized by the synthesis part to a mask on which a predetermined pattern is formed,
wherein the illumination system includes an optical path switching part configured to switch an optical path of the synthesized pulse light and to sequentially guide the light to the masks provided in plural.

65. The illumination optical system according to claim 63, comprising:
a synthesis device configured to synthesize the pulse lights emitted from each of the plurality of light sources,
wherein the delay optical system is configured to divide some of the pulse light synthesized by the synthesis device and to guide the pulse light to the second optical path.

66. The illumination optical system according to claim 63, wherein the delay optical system is configured to emit the pulse light through a plurality of routes, and to emit the pulse light to each of the plurality of optical path switching parts corresponding to the routes.

67. The illumination optical system according to claim 50, wherein the delay optical system is configured to transmit some of the pulse light, and to synthesize or divide the pulse light by reflecting a rest of the pulse light.

68. The illumination optical system according to claim 50, wherein the delay optical system is configured to synthesize or divide the pulse light on the basis of a polarization state of the pulse light.

69. The illumination optical system according to claim 50, further comprising a state changing part configured to make states of the pulse lights on the spatial light modulation element different from each other.

70. The illumination optical system according to claim 69, wherein the state changing part is configured to make states of the pulse lights on the spatial light modulation element different from each other by making wavelengths of the plurality of pulse lights different from each other.

71. The illumination optical system according to claim 69, wherein the state changing part is configured to make states of the pulse lights on the spatial light modulation element different from each other by making light emission timings of the plurality of pulse lights different from each other.

72. The illumination optical system according to claim 69, wherein, in a case the illumination system includes an optical path switching part configured to switch an optical path of the synthesized pulse light and to sequentially guides the light to the masks provided in plural, the state changing part is configured to make states of the pulse lights on the spatial light modulation element different from each other by making distribution timings of the pulse light by the optical path switching part different from each other.

73. The illumination optical system according to claim 50, wherein the mask is a spatial light modulator.

74. An exposure device comprising:
the illumination optical system according to claim 50;
a projection optical system configured to irradiate an exposure target with a light emitted from the mask illuminated by the pulse light and to divisionally expose an exposure target; and
a stage on which an exposure target is placeable.

75. The exposure device according to claim 74, wherein the light source is a laser light source whose emitting light wavelength is 360 nm or less, and
the projection optical system is constituted by one or two types of glass material.

76. The exposure device according to claim 75, wherein the glass material is quartz or fluorite.

77. The exposure device according to claim 74, wherein a pulse width of group pulse light in which the pulse lights delayed by a delay optical system are synthesized is set such that a product of flows of images according to a scanning speed of the exposure device is ⅓ or less of a resolution.

78. The exposure device according to claim 74, wherein the exposure target includes at least one side length or a diagonal length of 500 mm or more, and is a substrate for a flat panel display.

79. The exposure device according to claim 74, wherein the mask is a spatial light modulator.

80. A method for manufacturing a flat panel display, comprising:
exposing an exposure target using the exposure device according to claim 74; and
developing the exposed exposure target.
